(19) United States
(12) Patent Application Publication
(10) Pub. No.: US 2026/0155165 A1
(43) Pub. Date: Jun. 4, 2026

(54) MEMORY DEVICE, CIRCUIT, AND METHOD

(71) Applicant: TAIWAN SEMICONDUCTOR MANUFACTURING COMPANY, LTD., Hsinchu (TW)

(72) Inventors: Cheng Han LU, Hsinchu (TW); Chia-Fu LEE, Hsinchu (TW)

(21) Appl. No.: 18/966,606

(22) Filed: Dec. 3, 2024

(51) Int. Cl. G11C 11/16; G05F 1/56; H02M 3/07

(52) U.S. Cl. CPC G11C 11/1697; G05F 1/56; H02M 3/07; G11C 11/161

(57) ABSTRACT

A memory device includes a memory array, an analog bias generating circuit configured to generate at least one analog bias and supply the at least one analog bias to the memory array, an indicator circuit configured to provide a parameter signal indicating a parameter of the memory array, and a control circuit configured to adjust the analog bias generating circuit in response to the parameter signal provided by the indicator circuit.

### BACKGROUND

Integrated circuits (ICs) are widely used in various digital devices and/or applications in different areas. Memories, or memory devices, are components of IC devices and are configured to store data and/or applications to be processed and/or executed by the IC devices. As ICs as well as their memories have become more complex and/or reduced in size, there are considerations regarding reliability of read operations and/or write (or program) operations performed in the memories. Such considerations involve various voltages and/or currents supplied for the operations of the memories.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic diagram of a memory device, in accordance with some embodiments.

FIGS. 2A, 2B are schematic diagrams of various memory devices, in accordance with some embodiments.

FIGS. 3A, 3B, 3C, 3D are schematic diagrams of various memory devices, in accordance with some embodiments.

FIG. 4 is a schematic diagram of a memory device, in accordance with some embodiments.

FIGS. 5A, 5B, 5C, 5D are schematic circuit diagrams of various low-dropout (LDO) regulators and/or internal circuitry thereof, in accordance with some embodiments.

FIG. 6 is a schematic circuit diagram of a charge pump, in accordance with some embodiments.

FIG. 7 is a schematic circuit diagram of a band-gap reference circuit, in accordance with some embodiments.

FIG. 8 includes a schematic circuit diagram and a truth table of an encoder, in accordance with some embodiments.

FIG. 9 is a schematic diagram of a look-up table for a control circuit, in accordance with some embodiments.

FIG. 10 is a schematic diagram of a memory cell, in accordance with some embodiments.

FIG. 11 is a flowchart of a method, in accordance with some embodiments.

### DETAILED DESCRIPTION

The following disclosure provides many different embodiments, or examples, for implementing different features of the provided subject matter. Specific examples of components, values, operations, materials, arrangements, or the like, are described below to simplify the present disclosure. These are, of course, merely examples and are not intended to be limiting. Other components, values, operations, materials, arrangements, or the like, are contemplated. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed. Source/drain(s) may refer to a source or a drain, individually or collectively dependent upon the context.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In some embodiments, a memory device comprises at least one memory array and an analog bias generating circuit. The analog bias generating circuit is configured to generate at least one analog bias, e.g., an analog voltage or an analog current, and supply the at least one analog bias to the at least one memory array for one or more operations of the at least one memory array. The at least one memory array is a load to the analog bias generating circuit. A configuration or parameter of such a load is to be considered in configuring and/or operating the analog bias generating circuit to ensure that the at least one analog bias is adequately generated and supplied to the at least one memory array, for proper and reliable operations of the at least one memory array.

In some embodiments, an analog bias generating circuit is configured to be adjustable for operation over a range of different loads. Each of one or more memory arrays to be supplied with one or more analog biases from the analog bias generating circuit is equipped with an indicator circuit configured to provide a parameter signal indicating a parameter of the corresponding memory array. The parameter signal(s) indicating the parameter of the one or more memory arrays is/are input to a control circuit. The control circuit is configured to, based on the parameter signal(s), adjust the analog bias generating circuit to meet a load represented by the one or more memory arrays. As a result, a self-detect and/or self-adjust memory device configuration is obtained in one or more embodiments. In some embodiments, tasks for designing an analog bias generating circuit are simplified, because a single analog bias generating circuit design is usable with, and/or automatically optimizable for, various combinations of memory arrays. One or more further advantages and/or effects are achievable in accordance with one or more embodiments are described herein.

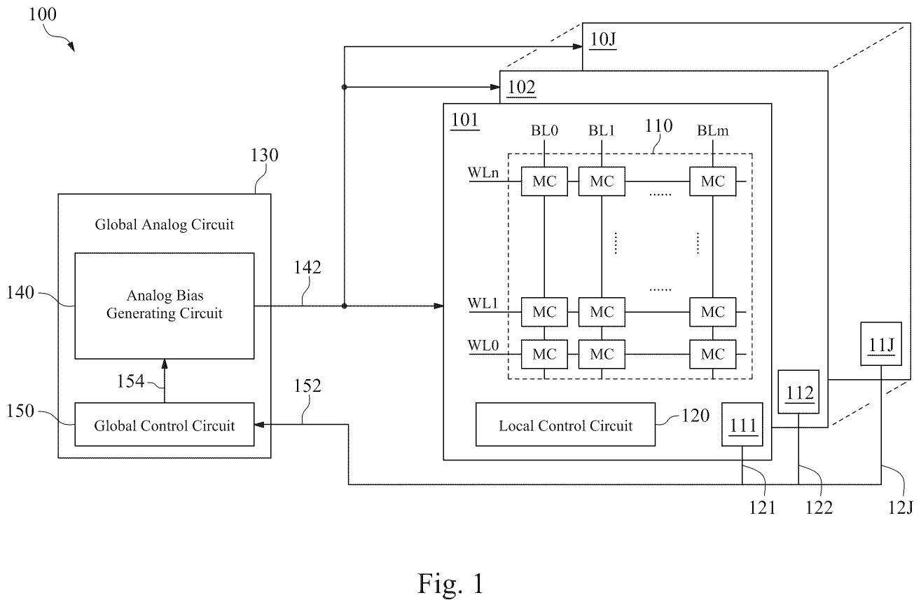

FIG. 1 is a schematic diagram of a memory device 100, in accordance with some embodiments. A memory device is a type of integrated circuit (IC) device. In at least one embodiment, a memory device is an individual IC device. In some embodiments, a memory device is included as a part of a larger IC device which comprises circuitry other than the memory device for other functionalities.

The memory device 100 comprises at least one memory macro and a memory controller. In the example configuration in FIG. 1, the memory device 100 comprises a plurality of memory macros 101, 102, . . . 10J, where J is a natural number, and the memory controller comprises a global analog circuit 130. In some embodiments, the memory controller comprises circuitry other than the global analog circuit 130.

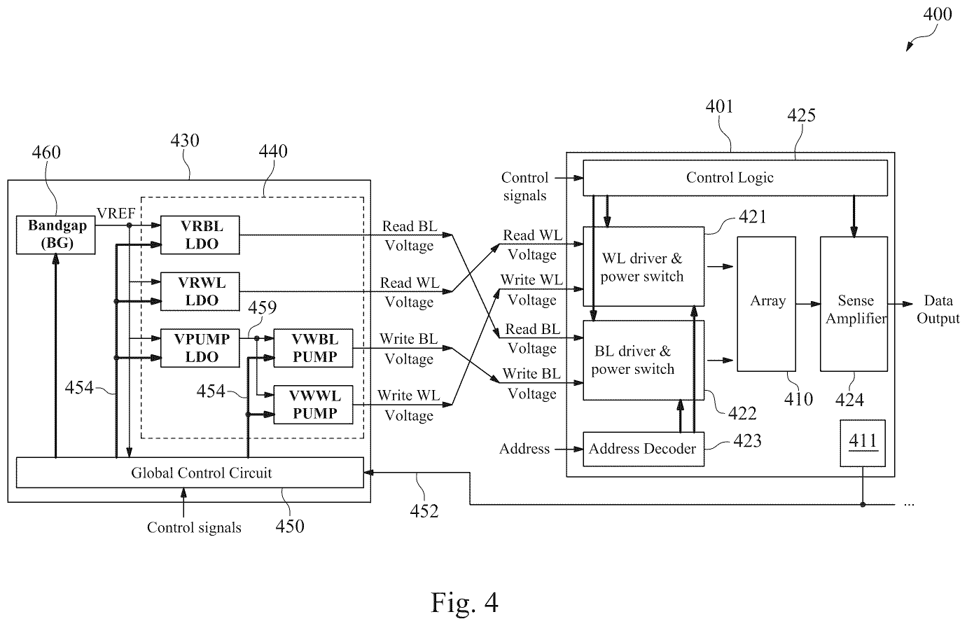

The memory macros 101, 102, . . . 10J are configured similarly. The memory macro 101 is described in detail herein, and detailed descriptions of the other memory macros are omitted. The memory macro 101 comprises a memory array 110 of memory cells MC, an indicator circuit 111 associated with the memory array 110, and a local control circuit 120. Example circuits in the local control circuit 120 (which is sometimes referred to as “control circuit”) in accordance with some embodiments are described with respect to FIG. 4.

A macro has a reusable configuration and is usable in various types or designs of IC devices. In some embodiments, the macro is understood in the context of an analogy to the architectural hierarchy of modular programming in which subroutines/procedures are called by a main program (or by other subroutines) to carry out a given computational function. In this context, an IC device uses the macro to perform one or more given functions. Accordingly, in this context and in terms of architectural hierarchy, the IC device is analogous to the main program and the macro is analogous to subroutines/procedures. In some embodiments, the macro is a soft macro. In some embodiments, the macro is a hard macro. In some embodiments, the macro is a soft macro which is described digitally in register-transfer level (RTL) code. In some embodiments, synthesis, placement and routing have yet to have been performed on the macro such that the soft macro can be synthesized, placed and routed for a variety of process nodes. In some embodiments, the macro is a hard macro which is described digitally in a binary file format (e.g., Graphic Database System II (GDSII) stream format), where the binary file format represents planar geometric shapes, text labels, other information and the like of one or more layout-diagrams of the macro in hierarchical form. In some embodiments, synthesis, placement and routing have been performed on the macro such that the hard macro is specific to a particular process node. A memory macro is a macro comprising memory cells which are addressable to permit data to be written to or read from the memory cells. In some embodiments, a memory macro further comprises circuitry configured to provide access to the memory cells and/or to perform a further function associated with the memory cells. The macro configuration described herein is an example. Other configurations are within the scopes of various embodiments.

The memory cells MC are arranged in a plurality of columns and rows of the memory array 110. The memory controller 120 is electrically coupled to the memory cells MC and configured to control operations of the memory cells MC including, but not limited to, a read operation, a write operation (or program operation), or the like. Read operations and write operations are sometimes commonly referred to as access operations.

The memory array 110 comprises a plurality of word lines (also referred to as “address lines”) WL0, WL1 to WLn extending along a row direction (i.e., the horizontal direction in FIG. 1) of the rows, and a plurality of bit lines (also referred to as “data lines”) BL0, BL1 to BLm extending along a column direction (i.e., the vertical direction in FIG. 1) of the columns, where n and m are natural numbers. The word lines are commonly referred to herein as “WL,” and the bit lines are commonly referred to herein as “BL.” The memory cells MC in each row are electrically coupled to the memory controller 120 by a corresponding word line. In some example operations, word lines are configured for transmitting addresses of the memory cells MC to be read from, or for transmitting addresses of the memory cells MC to be written to, or the like. In some example operations, bit lines are configured for transmitting data read from the memory cells MC indicated by corresponding word lines, or for transmitting data to be written to the memory cells MC indicated by corresponding word lines, or the like. In some embodiments, instead of a single word line WL and/or a single bit line BL, each memory cell MC is coupled to a pair of word lines and/or a pair of bit lines. In at least one embodiment, a pair of word lines coupled to a memory cell MC comprises a write word line (WWL) and a read word line (RWL), and/or a pair of bit lines coupled to a memory cell MC comprises a pair of differential bit lines, e.g., a bit line and a bit line bar (BLB). In some embodiments, the memory array 101 comprises a plurality of source lines (not shown) coupled to the memory cells MC along the rows or along the columns. Source lines are further examples of data lines, and are sometimes commonly referred to as “SL”.

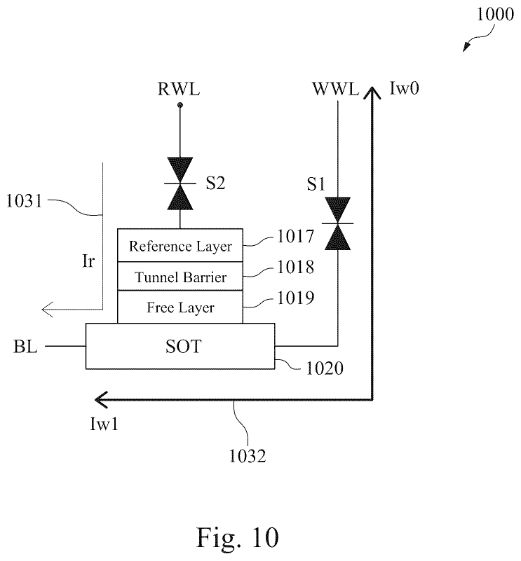

In some embodiments, the memory cells MC comprise memory cells of a spin-orbit torque (SOT) magnetoresistive random-access memory (MRAM), a spin-transfer torque (STT) MRAM, a resistive RAM (RRAM or ReRAM), a phase-change memory (PCM), a ferroelectric RAM (FeRAM), an electrochemical RAM (ECRAM), or the like. An example SOT MRAM memory cell is described with respect to FIG. 10. Various memory cell configurations and/or numbers of word lines and/or bit lines and/or source lines in a memory array are within the scope of various embodiments.

The global analog circuit 130 comprises an analog bias generating circuit 140 and a global control circuit 150 (which is sometimes referred to as “control circuit”). The analog bias generating circuit 140 is configured to generate at least one analog bias, and supply the at least one analog bias to the memory arrays of the memory macros 101, 102, . . . 10J. For simplicity, “analog bias” is sometimes referred to as “bias.” In the example configuration in FIG. 1, the analog bias generating circuit 140 is configured to generate and supply a plurality of biases 142 to the memory arrays. In some embodiments, the same biases 142 are supplied to the memory arrays of the memory macros 101, 102, . . . 10J. In at least one embodiment, different biases 142 are supplied to the memory arrays of the memory macros 101, 102, . . . 10J. Example biases comprise various analog voltages and/or currents supplied to the memory arrays during one or more access operations of the memory arrays. In some non-limiting embodiments described with respect to FIG. 4 and/or FIG. 10, biases comprise one or more of read and/or write word line voltages, read and/or write bit line voltage, inhibition voltages, reference voltages, or the like.

In some embodiments, an analog bias generating circuit is configured to generate and supply biases in consideration of the load, i.e., configurations and/or parameters of memory arrays coupled to receive the biases from the analog bias generating circuit. For example, when the load is high, e.g., when a high number of memory cells are coupled to an analog bias generating circuit, there is a concern that memory cells located far away from the analog bias generating circuit potentially receive insufficient biases, due to one or more factors, such as voltage drop, or the like. As a result, there is a risk that access operations at such memory cells are potentially unreliable and/or incorrect. In such situations, the analog bias generating circuit is configured to generate and supply the biases with a high driving strength sufficient to deliver the biases to the memory cells farthest from the analog bias generating circuit, to ensure reliable and correct access operations. However, an analog bias generating circuit with a high driving strength has an increased power consumption and is not necessary when the load is low, i.e., when a low number of memory cells are coupled to the analog bias generating circuit. As a result, when the load is low, the analog bias generating circuit is configured to have a reduced driving strength to still ensure reliable and correct access operations, but without unnecessarily high power consumption.

The tasks of designing or configuring an analog bias generating circuit in consideration of various aspects described above, i.e., sufficient biases and reasonable power consumption, become even more challenging in situations where one or more memory arrays are configured by one party, e.g., a customer, whereas the analog bias generating circuit is configured by another party, i.e., a chip designer or maker. In some situations, the chip designer/maker has to wait for the customer to complete, or at least select, their memory array configuration before configuring an analog bias generating circuit corresponding to the customer's memory array configuration. In one or more situations, when the customer makes a change to their memory array configuration, the chip designer/maker has to redesign or reconfigure the analog bias generating circuit accordingly. The described process of configuring and/or reconfiguring an analog bias generating circuit for a specific memory array configuration is sometimes time-consuming and/or inefficient.

In some embodiments, to address one or more aspects described above, the analog bias generating circuit 140 is configured to be adjustable, and information indicating a parameter of one or more of the memory macros 101, 102, . . . 10J is provided to the global analog circuit 130 and is used to adjust the analog bias generating circuit 140 accordingly.

Specifically, the memory macros 101, 102, . . . 10J correspondingly comprise indicator circuits 111, 112, . . . 11J which are configured to correspondingly provide parameter signals 121, 122, . . . to 12J each indicating a parameter of the memory array in the corresponding memory macro. For example, the parameter signal 121 indicates a parameter of the memory array 110 in the memory macro 101, the parameter signal 122 indicates a parameter of a memory array (not shown) in the memory macro 102, or the like. The parameter signals 121, 122, . . . to 12J are commonly referred to as an input signal 152 which is provided to the global control circuit 150 of the global analog circuit 130. The global control circuit 150 is configured to, based on the input signal 152, generate one or more control signals 154 to adjust the analog bias generating circuit 140. As a result, in one or more embodiments, the analog bias generating circuit 140 is automatically optimized for the specific parameters of the memory arrays coupled thereto.

In some embodiments, the parameter indicated to the global control circuit 150 by a parameter signal among the parameter signals 121, 122, . . . to 12J comprises a density of the corresponding memory array. For example, the parameter signal 121 indicates the density of the memory array 110. In at least one embodiment, a density of a memory array corresponds to the number of memory cells, or the size, of the memory array. In a non-limiting example, a memory array having a size of 16 Mb is considered to have a density of 16 Mb. In a further non-limiting example, a memory array having a size of 2 Mb is considered to have a density of 2 Mb. In some embodiments, a memory macro is considered to have a density corresponding to the total density of all memory arrays included in the memory macro. For example, a memory macro that has a single 16 Mb memory array is considered to have a density of 16 Mb. For another example, a memory macro that includes two 16 Mb memory arrays is considered to have a density of 32 Mb. In at least one embodiment, the indicator circuit in each memory macro is configured to generate a parameter signal indicating the density of the memory macro, i.e., the total density of all memory arrays in the memory macro.

In some embodiments, when a memory macro, e.g., memory macro 101, is designed or configured, e.g., by a customer, it is sufficient to configure the corresponding indicator circuit, e.g., indicator circuit 111, to generate a corresponding parameter signal, e.g., parameter signal 121, which indicates the density of all memory arrays included in the memory macro 101. When or if the customer changes the density of a memory array in the memory macro 101, the customer also reconfigures the indicator circuit 111 to reflect the change. In at least one embodiment, reconfiguring the indicator circuit 111 is as simple as adding or changing a bit in a storage circuit, or indicating a different resistance value for a resistor, as described with respect to some embodiments herein. The indicator circuits in the other memory macros 102, . . . 10J are configured and/or re-configured similarly.

In some embodiments, the densities of the memory macros 101, 102, . . . 10J are not required to be provided to the designer of the analog bias generating circuit 140 during the designing stage. In one or more embodiments, the densities of the memory macros 101, 102, . . . 10J are not provided to the analog bias generating circuit 140 until the memory device 100 has been manufactured. In at least one embodiment, when the memory device 100 is powered up, e.g., for the very first time after being manufactured, the indicator circuits 111, 112, . . . 11J are caused to correspondingly generate parameter signals 121, 122, . . . to 12J indicating the densities of the corresponding memory macros 101, 102, . . . 10J. In some embodiments, the parameter signals 121, 122, . . . to 12J are digital signals. In further embodiments, the parameter signals 121, 122, . . . to 12J are analog signals. The parameter signals 121, 122, . . . to 12J are supplied to the global control circuit 150 in the form of the input signal 152 which indicates the total density of all memory arrays in all of the memory macros 101, 102, . . . 10J. Based on density information indicating the total density of all memory arrays in the input signal 152, the global control circuit 150 is configured to adjust, or optimize, the analog bias generating circuit 140 accordingly, through the control signals 154. The adjusted or optimized analog bias generating circuit 140 is configured to generate and supply the biases 142 to the memory macros 101, 102, . . . 10J in a manner, e.g., with a driving strength, sufficient to ensure reliable and correct access operations of the corresponding memory arrays, and with reasonable power consumption at the analog bias generating circuit 140.

In some embodiments, after successfully receiving the density information upon powering up, the global control circuit 150 is configured to stop receiving the input signal 152, or if the input signal 152 is continued to be received, it is ignored by the global control circuit 150. In an example configuration, the global control circuit 150 comprises a switch (not shown) at an input configured to receive the input signal 152. The global control circuit 150 is configured to turn OFF the switch to stop receiving the input signal 152 upon expiration of a predetermined time period since powering up. The predetermined time period is sufficient to ensure that the density information is received and the analog bias generating circuit 140 is successfully optimized based on the density information. Although several embodiments specifically described herein use the density of a memory array or a memory macro as a parameter to be used for adjusting the analog bias generating circuit 140, one or more parameters other than density are within the scopes of various embodiments, provided that such one or more parameters are factors to be considered in the generation and/or supply of the biases 142 to the memory macros 101, 102, . . . 10J.

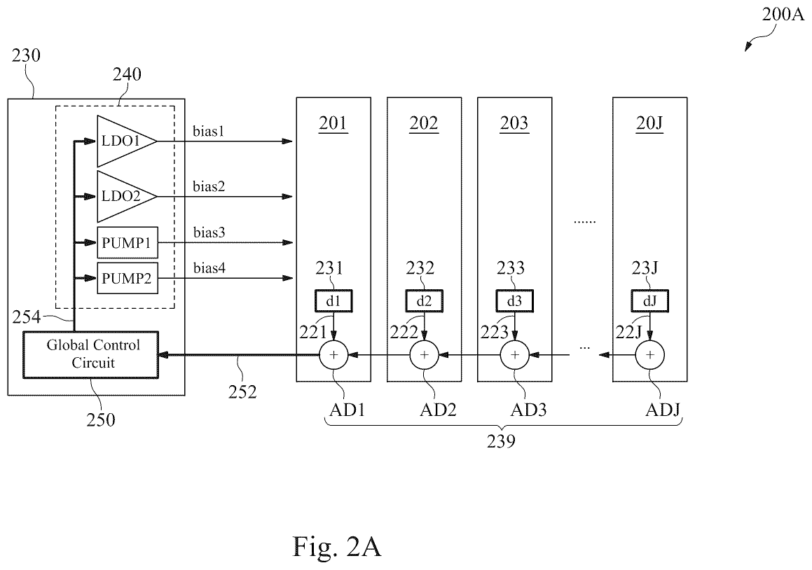

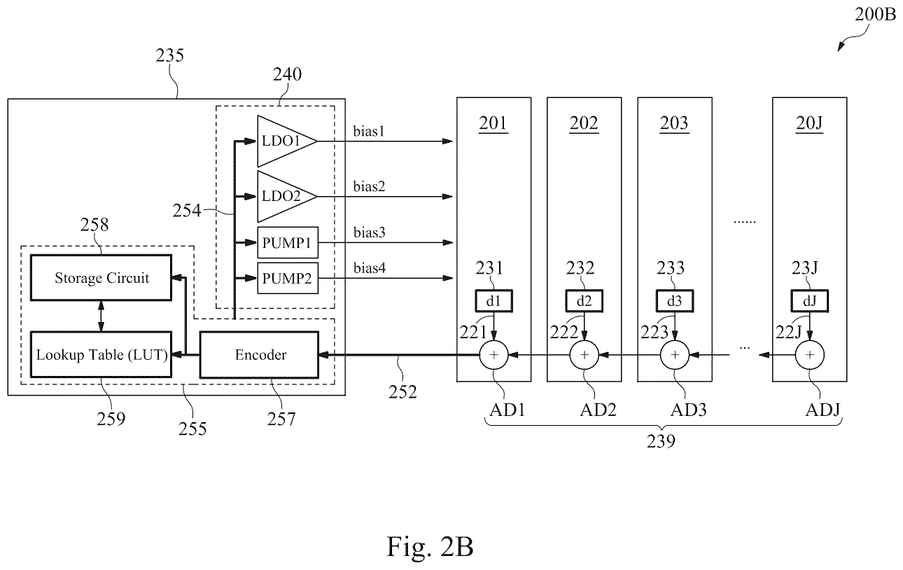

FIG. 2A is a schematic diagram of a memory device 200A, in accordance with some embodiments. In some embodiments, the memory device 200A corresponds to the memory device 100.

The memory device 200A comprises a plurality of memory macros 201, 202, 203, . . . 20J, and a global analog circuit 230. The global analog circuit 230 comprises an analog bias generating circuit 240 and a global control circuit 250. In some embodiments, the memory macros 201, 202, 203, . . . 20J, global analog circuit 230, analog bias generating circuit 240, global control circuit 250 correspond to the memory macros 101, 102, . . . 10J, global analog circuit 130, analog bias generating circuit 140, global control circuit 150. For simplicity, various components of the memory device 200A are omitted from FIG. 2A. For example, one or more memory arrays and a local control circuit in each of the memory macros 201, 202, 203, . . . 20J are not illustrated in FIG. 2A.

In the memory device 200A, each of the memory macros 201, 202, 203, . . . 20J comprises an indicator circuit corresponding to one of the indicator circuits 111, 112, . . . 11J, and comprising a storage circuit and an adder. For example, the indicator circuit of the memory macro 201 comprises a storage circuit 231 coupled to an adder AD1, the indicator circuit of the memory macro 202 comprises a storage circuit 232 coupled to an adder AD2, the indicator circuit of the memory macro 203 comprises a storage circuit 233 coupled to an adder AD3, and the indicator circuit of the memory macro 20J comprises a storage circuit 23J coupled to an adder ADJ.

Each of the storage circuits 231, 232, 233, . . . 23J is configured to store a corresponding value of a parameter of the corresponding memory macro. For example, the storage circuit 231 is configured to store a value d1 of the density of the memory macro 201, the storage circuit 232 is configured to store a value d2 of the density of the memory macro 202, the storage circuit 233 is configured to store a value d3 of the density of the memory macro 203, and the storage circuit 23J is configured to store a value dJ of the density of the memory macro 20J.

In some embodiments, each of the storage circuits 231, 232, 233, . . . 23J comprises any circuit configured to store a digital datum or digital data. In at least one embodiment, the digital datum or digital data is/are stored permanently, e.g., by hardwiring, in the corresponding storage circuit and is/are not changeable after manufacture. In at least one embodiment, each of the storage circuits 231, 232, 233, . . . 23J comprises one or more transistors each corresponding to one bit. A transistor tied to a node of a positive power supply voltage (e.g., VDD) corresponds to one of logic “1” and logic “0 ,” whereas a transistor tied to a node of a reference power supply voltage, e.g., the ground (VSS), corresponds to the other of logic “1” and logic “0.” In an example, there are two density options, e.g., 16 Mb and 2 Mb, for the memory macros 201, 202, 203, . . . 20J, and a single bit is sufficient for each of the storage circuits 231, 232, 233, . . . 23J to store the corresponding density value d1, d2, d3, . . . dJ. Specifically, a storage circuit having a single transistor tied to VDD stores a bit of logic “1” which indicates that the density of the corresponding memory macro is 16 Mb, whereas a storage circuit having a single transistor tied to VSS stores a bit of logic “0 ” which indicates that the density of the corresponding memory macro is 2 Mb. In another example, there are more than two density options for the memory macros 201, 202, 203, . . . 20J, and each of the storage circuits 231, 232, 233, . . . 23J has two or more bits to store the corresponding density value d1, d2, d3, . . . dJ. Specifically, storage circuits each having two bits (e.g., two transistors each configured to store logic “0” or logic “1”) are configured to cover up to four density options, whereas storage circuits each having three bits are configured to cover up to eight density options, or the like. The described storage circuit configuration comprising one or more transistors hardwired for data storage is an example. Other storage circuit configurations are within the scopes of various embodiments.

An output of each of the storage circuits is coupled to an input of the corresponding adder. For example, the output of the storage circuit 231 is coupled to a first input of the adder AD1, the output of the storage circuit 232 is coupled to a first input of the adder AD2, the output of the storage circuit 233 is coupled to a first input of the adder AD3, and the output of the storage circuit 23J is coupled to a first input of the adder ADJ. In at least one embodiment, where a storage circuit is configured to store one bit, the output of the storage circuit is a 1-bit output and the first input of the corresponding adder is a 1-bit input. In at least one embodiment, where a storage circuit is configured to store two bits, the output of the storage circuit is a 2-bit output and the first input of the corresponding adder is a 2-bit input, or the like.

The adders AD1, AD2, AD3, . . . ADJ are similarly configured and are serially coupled with each other into a string of adders, or adder string, 239. The adder string 239 is further coupled to the global control circuit 250. Specifically, an output of each of the adders AD2, AD3, . . . ADJ is coupled to a second input of a subsequent adder in the adder string 239, i.e., to the second input of the adders AD1, AD2, . . . AD( J-1), where the adder AD(J-1) is not shown in FIG. 2A. The second input of the adder ADJ at one end of the adder string 239 is floating, and the output of the adder AD1 at the other end of the adder string 239 is coupled to an input of the global control circuit 250.

In some embodiments, upon powering up the memory device 200A, the storage circuits 231, 232, 233, . . . 23J are configured to output the corresponding density values d1, d2, d3, . . . dJ as corresponding parameter signals 221, 222, 223, . . . 22J to the corresponding adders AD1, AD2, AD3, . . . ADJ. Except for the adder ADJ which outputs the corresponding density value dJ to the adder AD(J-1) (not shown), the other adders in the adder string 239 sequentially add up the density values d1, d2, d3, . . . dJ and generate, at the output of the adder AD1, an input signal 252 corresponding to the sum of the density values d1, d2, d3, . . . dJ. In other words, the input signal 252 includes density information of the total density of all memory macros 201, 202, 203, . . . 20J.

The global control circuit 250 is configured to, based on the density information included in the input signal 252, generate control signals 254 to adjust one or more adjustable circuit elements in the analog bias generating circuit 240.

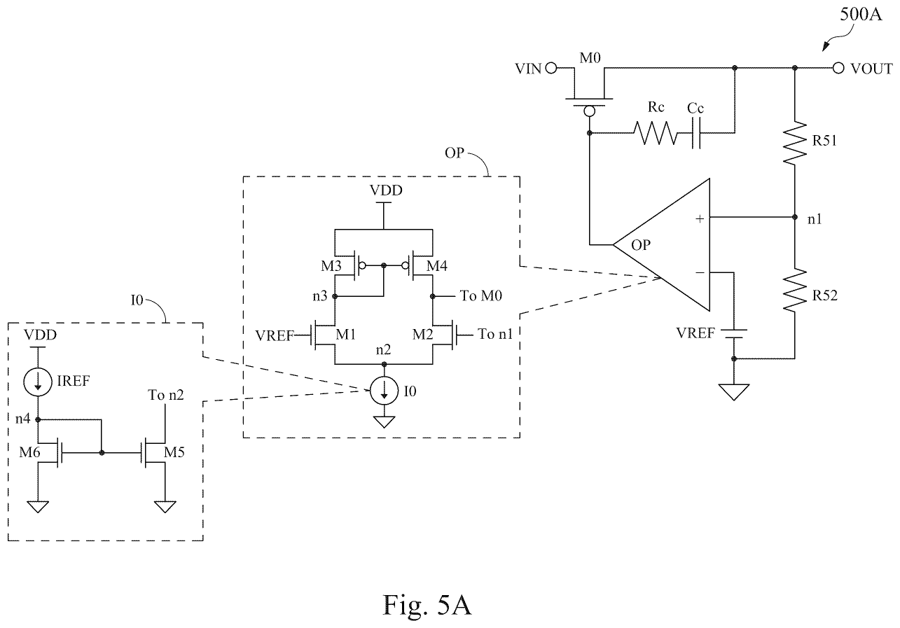

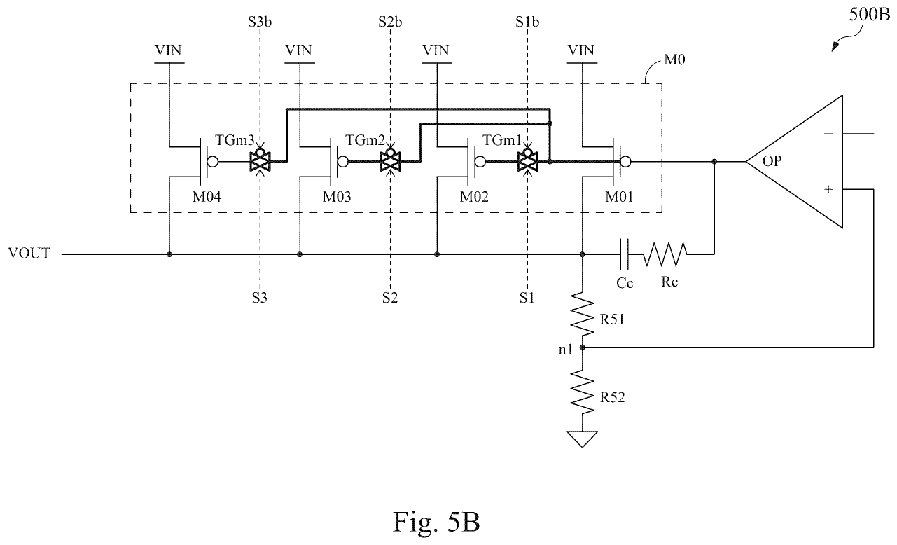

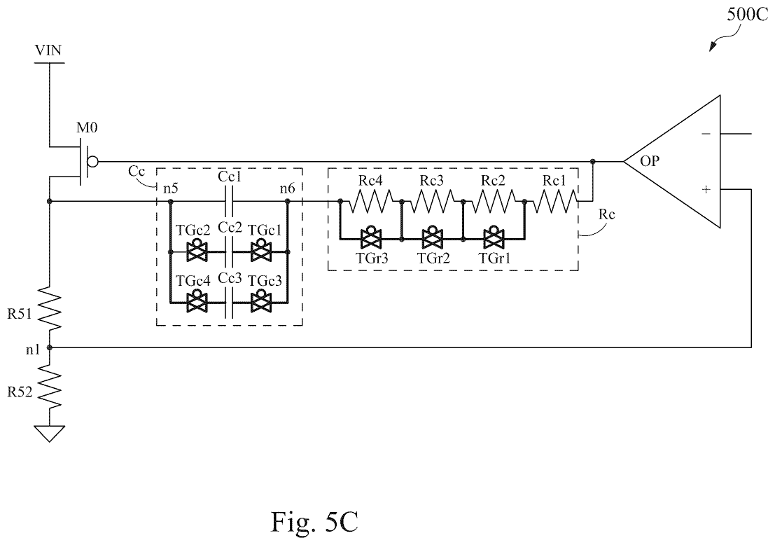

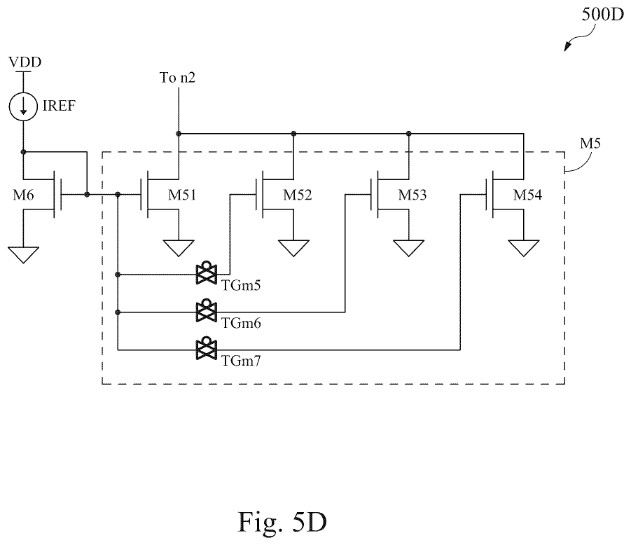

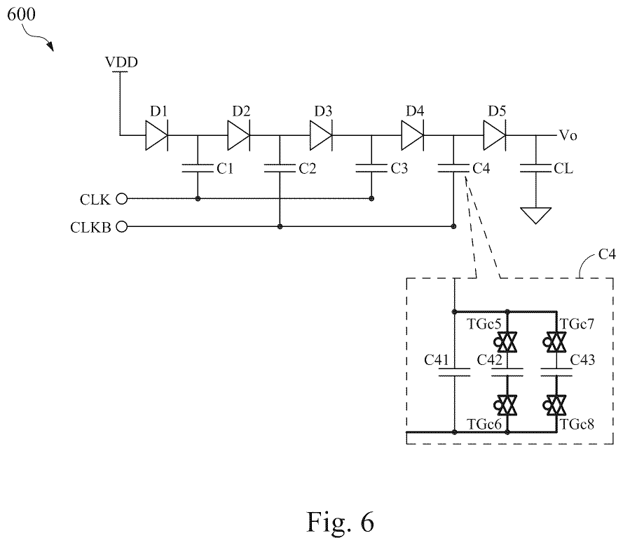

In the example configuration in FIG. 2A, the analog bias generating circuit 240 comprises low-dropout (LDO) regulators LDO1, LDO2 and charge pumps PUMP1, PUMP2 configured to generate and supply corresponding biases, i.e., bias1 to bias4, to the memory macros 201, 202, 203, . . . 20J. In at least one embodiment, one or more of the regulators LDO1, LDO2 and charge pumps PUMP1, PUMP2 are adjustable circuit elements which are adjustable by one or more of the control signals 254. In some embodiments, at least one of driving or phase margin of an adjustable LDO regulator is adjustable by one or more of the control signals 254. In at least one embodiment, driving of an adjustable charge pump is adjustable by one or more of the control signals 254. Examples of adjustable LDO regulators are described with respect to FIGS. 5A-5D, and one or more examples of adjustable charge pumps are described with respect to FIG. 6. One or more advantages described herein are achievable by the memory device 200A, in accordance with some embodiments.

FIG. 2B is a schematic diagram of a memory device 200B, in accordance with some embodiments. In some embodiments, the memory device 200B corresponds to one or more of the memory devices 100, 200A. Components in FIG. 2B having corresponding components in FIG. 2A are designated by the same reference numerals as in FIG. 2A.

Compared to the memory device 200A, the memory device 200B comprises a global analog circuit 235 comprising the analog bias generating circuit 240 and a global control circuit 255. The global control circuit 255 is configured to receive the input signal 252 and generate the control signals 254 for adjusting one or more circuit elements of the analog bias generating circuit 240. The global control circuit 255 comprises an encoder 257, a storage circuit 258, and a look-up table (LUT) 259.

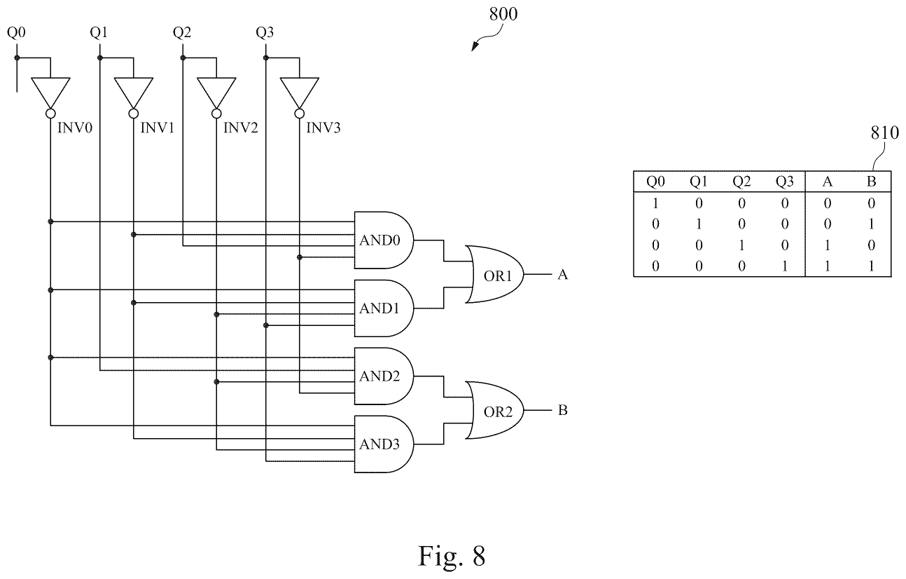

The encoder 257 is coupled to the adder string 239 to receive the input signal 252 corresponding to the sum of the density values d1, d2, d3, . . . dJ of all memory macros 201, 202, 203, . . . 20J, and is configured to generate an encoded value of the sum of the density values d1, d2, d3, . . . dJ. In at least one embodiment, the encoder 257 is an N-bit encoder, and each of the adders AD1, AD2, AD3, . . . ADJ is an N-bit adder, where N is natural number. In some embodiments, the value of N is predetermined based on the number of density options, as described herein. Additionally or alternatively, the value of N is predetermined based on a maximum density and/or a minimum density configurable for an memory macro, in accordance with one or more memory design specifications. An example configuration of an encoder is described with respect to FIG. 8. In some embodiments, the encoder 257 is omitted, and the input signal 252, which is already in the digital form, is directly used for generating one or more of the control signals 254, as described herein.

In the example configuration in FIG. 2B, the storage circuit 258 is coupled to the encoder 257 to receive the encoded value of the sum of the density values d1, d2, d3, . . . dJ. In at least one embodiment where the encoder 257 is omitted, the storage circuit 258 is configured to receive the input signal 252 and store the sum of the density values d1, d2, d3, . . . dJ directly. In either configuration, the storage circuit 258 is considered to store density information corresponding the sum of the density values d1, d2, d3, . . . dJ. In some embodiments where the global control circuit 255 stops receiving the input signal 252 after powering up for the very first time, the density information stored in the storage circuit 258 ensures that the total density of the memory macros 201, 202, 203, . . . 20J will not be lost, and will be usable for adjusting the analog bias generating circuit 240 should the need for adjustment arise again. In at least one embodiment, the storage circuit 258 comprises a writeable non-volatile data storage device. In some embodiments, the storage circuit 258 is omitted.

In the example configuration in FIG. 2B, the LUT 259 is coupled to the encoder 257 and the storage circuit 258. In some embodiments, the LUT 259 is coupled to one of the encoder 257 and the storage circuit 258. In some embodiments, where the encoder 257 and the storage circuit 258 are omitted, the LUT 259 is coupled to receive the input signal 252. In some embodiments, the LUT 259 is stored in a region of the storage circuit 258, or on a separate storage circuit. In at least one embodiment, the storage circuit storing the LUT 259 is a read-only data storage device, or the region storing the LUT 259 is marked as read-only to prevent the data in the LUT 259 from being written over.

In some embodiments, the data in the LUT 259 are predetermined, e.g., from one or more simulations of operations of various configurations of the analog bias generating circuit 240 operating over a range of different loads, e.g., different values of the total density of the memory arrays to be coupled to the analog bias generating circuit 240. Each of the different values of the total density is stored in the LUT 259 in association with a configuration of the analog bias generating circuit 240 determined to be optimal from the one or more simulations.

In an example, the LUT 259 is configured to store different values of the total density, e.g., the sum of the density values d1, d2, d3, . . . dJ, in association with corresponding adjustments to be made by the global control circuit 255 to the analog bias generating circuit 240. The adjustments correspond to the optimal configurations of the analog bias generating circuit 240 predetermined through one or more simulations as described. In response to a specific value of the total density input into the LUT 259 from the storage circuit 258 or from the input signal 252, the LUT 259 is configured to return the corresponding adjustments based on which the control signals 254 are generated, by further circuitry or logic (not shown) of the global control circuit 255, to bring the analog bias generating circuit 240 to the configuration predetermined as optimal for the specific value of the total density.

In another example, the LUT 259 is configured to store different encoded values of the total density, e.g., the sum of the density values d1, d2, d3, . . . dJ, in association with corresponding adjustments to be made by the global control circuit 255 to the analog bias generating circuit 240. The adjustments correspond to the optimal configurations of the analog bias generating circuit 240 predetermined through one or more simulations as described. In response to a specific encoded value of the total density input into the LUT 259 from the storage circuit 258 or from the encoder 257, the LUT 259 is configured to return the corresponding adjustments based on which the control signals 254 are generated, by further circuitry or logic (not shown) of the global control circuit 255, to bring the analog bias generating circuit 240 to the configuration predetermined as optimal for the specific encoded value of the total density.

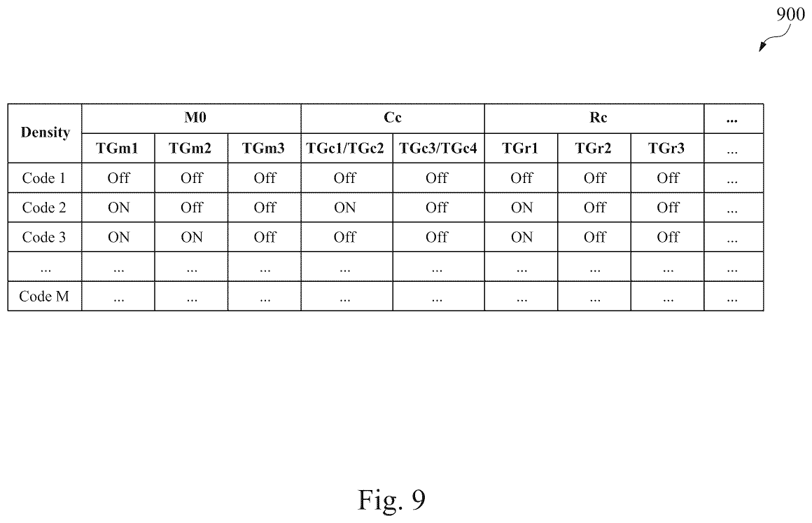

In some embodiments, the LUT 259 is accessed once, e.g., upon powering up the memory device 200B for the very first time, and the adjustments returned from the LUT 259 are stored in the storage circuit 258 for later retrieval and use for adjusting the analog bias generating circuit 240 should the need for adjustment arise again. A non-limiting example of data stored in the LUT 259 is described with respect to FIG. 9. In some embodiments, the LUT 259 is omitted. In such embodiments, the global control circuit 255 comprises further logic or circuitry (not shown) configured to generate the control signals 254 based on the sum of the density values d1, d2, d3, . . . dJ, or an encoded value thereof, without resorting to predetermined data such as those described with respect to LUT 259. The described configuration of the global control circuit 255 is an example. Other configurations for the global control circuit 255 are within the scopes of various embodiments. One or more advantages described herein are achievable by the memory device 200B, in accordance with some embodiments.

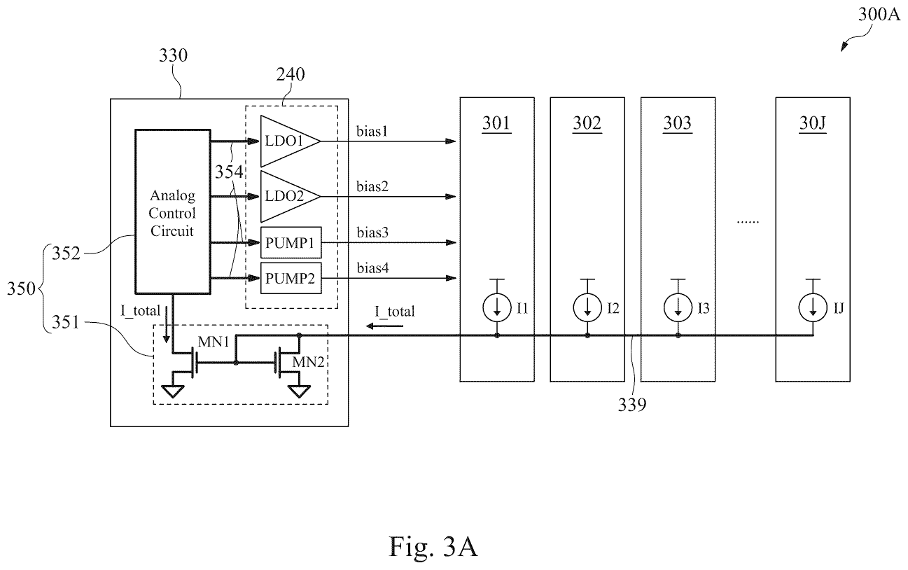

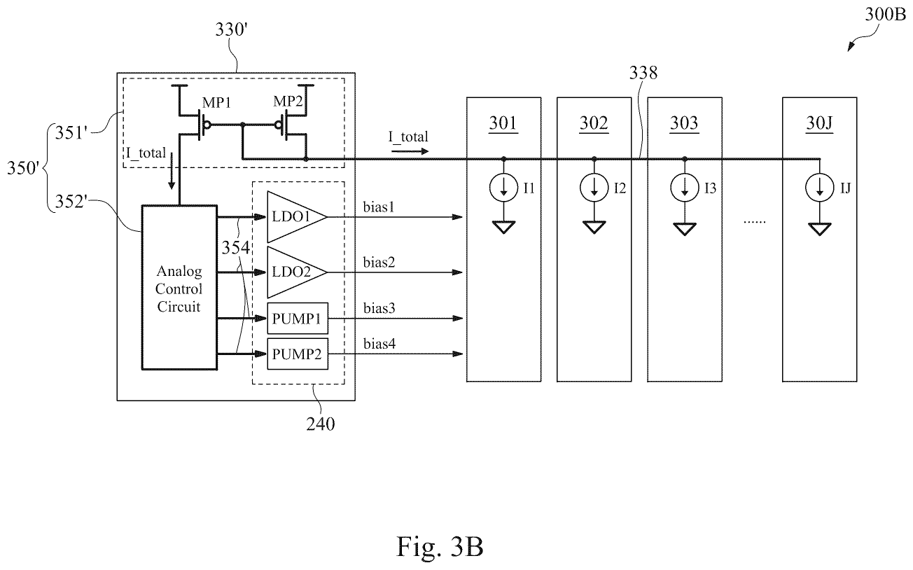

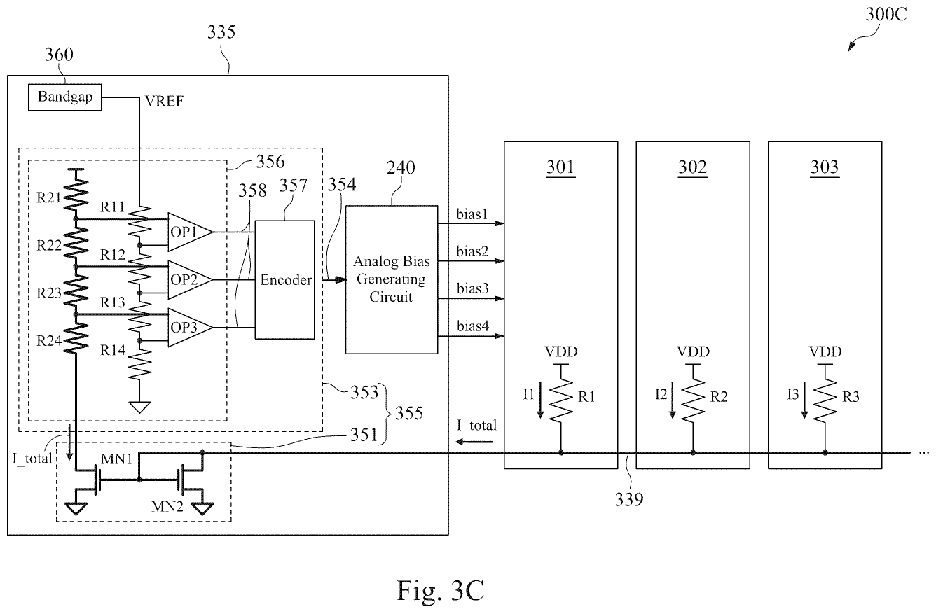

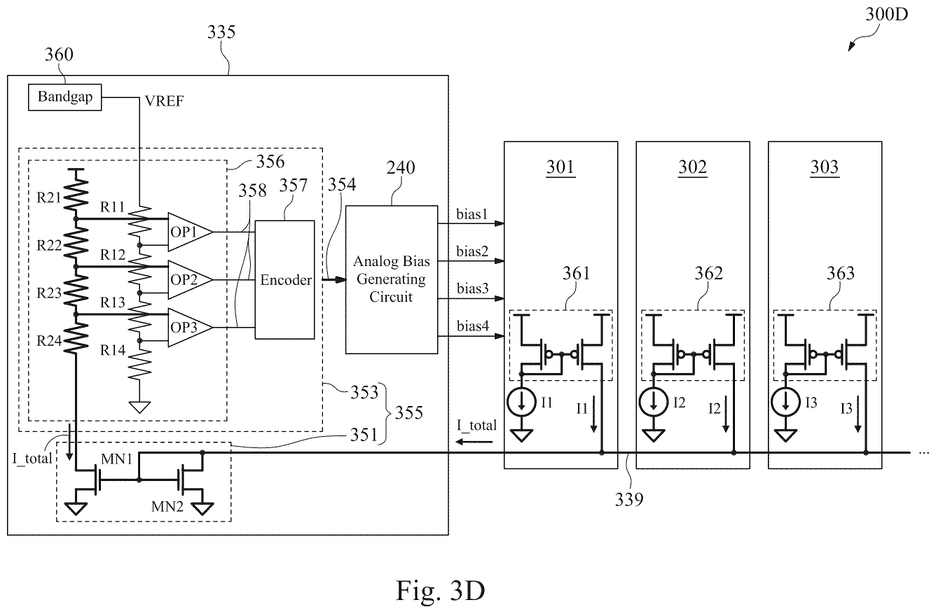

In the example configurations described with respect to FIGS. 2A-2B, parameter signals provided from the memory macros are digital signals. Further example configurations in which parameter signals provided from the memory macros are analog signals are described with respect to FIGS. 3A-3D.

FIG. 3A is a schematic diagram of a memory device 300A, in accordance with some embodiments. In some embodiments, the memory device 300A corresponds to one or more of the memory devices 100, 200A, 200B. Components in FIG. 3A having corresponding components in FIGS. 2A, 2B are designated by the same reference numerals as in FIGS. 2A, 2B.

The memory device 300A comprises a plurality of memory macros 301, 302, 303, . . . 30J, and a global analog circuit 330. The global analog circuit 330 comprises the analog bias generating circuit 240 and a global control circuit 350. In some embodiments, the memory macros 301, 302, 303, . . . 30J, global analog circuit 330, analog bias generating circuit 240, global control circuit 350 correspond to the memory macros 101, 102, . . . 10J, global analog circuit 130, analog bias generating circuit 140, global control circuit 150. For simplicity, various components of the memory device 300A are omitted from FIG. 3A. For example, one or more memory arrays and a local control circuit in each of the memory macros 301, 302, 303, . . . 30J are not illustrated in FIG. 3A.

In the memory device 300A, each of the memory macros 301, 302, 303, . . . 30J comprises an indicator circuit corresponding to one of the indicator circuits 111, 112, . . . 11J, and comprising a current source. For example, the indicator circuit of the memory macro 301 comprises a current source I1, the indicator circuit of the memory macro 302 comprises a current source I2, the indicator circuit of the memory macro 303 comprises a current source I3, and the indicator circuit of the memory macro 30J comprises a current source IJ. For simplicity, a current source and a current generated by the current source are designated by the same reference numeral. For example, a current generated by the current source I1 is also designated as I1.

A current generated by each of the current sources I1, I2, I3, . . . IJ corresponds to a value of a parameter of the corresponding memory macro. For example, the current I1 corresponds to a density of the memory macro 301, the current I2 corresponds to a density of the memory macro 302, the current I3 corresponds to a density of the memory macro 303, and the current IJ corresponds to a density of the memory macro 30J. In an example, there are two density options, e.g., 16 Mb and 2 Mb, for the memory macros 301, 302, 303, . . . 30J, and there are two corresponding current values for the currents I1, I2, I3, . . . IJ. For example, the current I1 has a first current value which indicates that the density of the corresponding memory macro 301 is 16 Mb, whereas the current I2 has a different, second current value which indicates that the density of the corresponding memory macro 302 is 2 Mb, or the like. In another example, there are K density options for the memory macros 301, 302, 303, . . . 30J, where K is a natural number greater than 2, and there are correspondingly K current values for the currents I1, I2, I3, . . . IJ.

An output of each of the current sources I1, I2, I3, . . . IJ is coupled to the global control circuit 350 through a conductor 339. As a result, a total current I_total being a sum of the currents I1, I2, I3, . . . IJ generated by the corresponding current sources is supplied to the global control circuit 350. The current I_total corresponds to a total density of the memory macros 301, 302, 303, . . . 30J.

The global control circuit 350 comprises a current mirror circuit 351 and an analog control circuit 352 coupled to the current mirror circuit 351. The current mirror circuit 351 comprises a pair of N-type transistors MN1, MN2.

The transistor MN1 comprises a source/drain coupled to the analog control circuit 352, another source/drain coupled to the ground or VSS, and a gate coupled to a gate of the transistor MN2. The transistor MN2 comprises a source/drain coupled to the gates of the transistors MN1, MN2, and to the conductor 339, and another source/drain coupled to the ground or VSS. The current mirror circuit 351 is configured to mirror the current I_total supplied to the transistor MN2 from the conductor 339, to cause the same current I_total to flow through the transistor MN1. As a result, the current I_total is effectively supplied to the analog control circuit 352.

The analog control circuit 352 is configured, based on density information about the total density of the densities of the memory macros 301, 302, 303, . . . 30J included in the current I_total supplied to the analog control circuit 352 through the current mirror circuit 351, to generate control signals 354 to adjust one or more adjustable circuit elements in the analog bias generating circuit 240. In some embodiments, the global control circuit 350 is configured to receive the current I_total upon powering up the memory device 300A, and thereafter, stop receiving or ignore the current I_total, in a manner similar to one or more of the global control circuits 250, 255. One or more advantages described herein are achievable by the memory device 300A, in accordance with some embodiments.

FIG. 3B is a schematic diagram of a memory device 300B, in accordance with some embodiments. In some embodiments, the memory device 300B corresponds to one or more of the memory devices 100, 200A, 200B, 300A. Components in FIG. 3B having corresponding components in FIGS. 2A, 2B, 3A are designated by the same reference numerals as in FIGS. 2A, 2B, 3A.

Compared to the memory device 300A, the memory device 300B comprises a global analog circuit 330′ which comprises a global control circuit 350′ having a current mirror circuit 351′ and an analog control circuit 352′. The current mirror circuit 351′ includes a pair of P-type transistors MP1, MP2, instead of N-type transistors as in the current mirror circuit 351.

The transistor MP1 comprises a source/drain coupled to the analog control circuit 352′, another source/drain coupled to a positive power supply voltage, e.g., VDD, and a gate coupled to a gate of the transistor MP2. The transistor MP2 comprises a source/drain coupled to the gates of the transistors MP1, MP2, and to the current sources I1, I2, I3, . . . IJ through a conductor 338, and another source/drain coupled to VDD. The current I_total on the conductor 338 is a sum of the currents I1, I2, I3, . . . IJ generated by the corresponding current sources and corresponds to the total density of the memory macros 301, 302, 303, . . . 30J. The current mirror circuit 351′ is configured to mirror the current I_total supplied from the transistor MP2 to the conductor 338, to cause the same current I_total to flow through the transistor MP1 to the analog control circuit 352′. As a result, the current I_total is effectively supplied to the analog control circuit 352′, which is configured to, based on the current I_total, generate the control signals 354 to adjust one or more adjustable circuit elements in the analog bias generating circuit 240. In some embodiments, the global control circuit 350′ is configured to receive the current I_total upon powering up the memory device 300B, and thereafter, stop receiving or ignore the current I_total, in a manner similar to one or more of the global control circuits 250, 255. One or more advantages described herein are achievable by the memory device 300B, in accordance with some embodiments.

FIG. 3C is a schematic diagram of a memory device 300C, in accordance with some embodiments. In some embodiments, the memory device 300C corresponds to one or more of the memory devices 100, 200A, 200B, 300A, 300B. Components in FIG. 3C having corresponding components in FIGS. 2A, 2B, 3A, 3B are designated by the same reference numerals as in FIGS. 2A, 2B, 3A, 3B. For simplicity, memory macros beyond the memory macro 303 are not illustrated in FIG. 3C.

Compared to the memory device 300A, the indicator circuits in the memory macros 301, 302, 303, comprise resistors instead of current sources. For example, the indicator circuit of the memory macro 301 comprises a resistor R1 coupled between a node of a positive power supply voltage, e.g., VDD, and the conductor 339, the indicator circuit of the memory macro 302 comprises a resistor R2 coupled between VDD and the conductor 339, the indicator circuit of the memory macro 303 comprises a resistor R3 coupled between VDD and the conductor 339, or the like. For simplicity, a resistance value of a resistor and the resistor itself are designated by the same reference numeral. For example, the resistor R1 has a resistance value R1.

In some embodiments, each of the resistance values R1, R2, R3 corresponds to the density of the corresponding memory macros 301, 302, 303. In an example, there are two density options, e.g., 16 Mb and 2 Mb, for the memory macros 301, 302, 303, and there are two corresponding resistance values for the resistors R1, R2, R3. For example, the resistor R1 has a first resistance value which indicates that the density of the corresponding memory macro 301 is 16 Mb, whereas the resistor R2 has a different, second resistance value which indicates that the density of the corresponding memory macro 302 is 2 Mb, or the like. In another example, there are K density options for the memory macros 301, 302, 303, where K is a natural number greater than 2, and there are correspondingly K resistance values for the resistors R1, R2, R3. Because the resistance values R1, R2, R3 correspond to the densities of the memory macros 301, 302, 303, currents I1, I2, I3 also corresponding to the densities of the memory macros 301, 302, 303 are caused to flow through the resistors R1, R2, R3 to the conductor 339 upon powering up the memory device 300C. As a result, a current I_total corresponding to the total density of the memory macros 301, 302, 303 is caused to flow on the conductor 339.

The memory device 300C comprises a global analog circuit 335 comprising the analog bias generating circuit 240, a global control circuit 355, and a band-gap reference circuit 360. The global control circuit 355 comprises a current mirror circuit 351 coupled to the conductor 339, and an analog control circuit 353 coupled to receive the current I_total mirrored by the current mirror circuit 351 from the current I_total on the conductor 339.

The analog control circuit 353 comprises an analog-to-digital converter 356 and an encoder 357. The analog-to-digital converter 356 is coupled to the current mirror circuit 351, and configured to generate a digital signal 358 corresponding to the mirrored current I_total. The encoder 357 is coupled to the analog-to-digital converter 356 and configured to generate, from the digital signal 358, an encoded value corresponding to the total current. In some embodiments, the encoder 357 is omitted, and the digital signal 358 which is already in the digital form, is directly used for generating one or more of the control signals 354, in a manner similar to that described with respect to the memory device 200B. In some embodiments, the analog control circuit 353 further comprises a storage circuit corresponding to the storage circuit 258, and/or a look-up table corresponding to the LUT 259 for storing and/or generating one or more of the control signals 354, in a manner similar to that described with respect to the memory device 200B.

In the example configuration in FIG. 3C, the analog-to-digital converter 356 comprises a plurality of comparator circuits OP1, OP2, OP3, a first resistor ladder comprising resistors R11-R14, and a second resistor ladder comprising resistors R21-R24. Each of the comparator circuits OP1, OP2, OP3 comprises first and second inputs, and an output coupled to the encoder 357.

The first resistor ladder comprising the resistors R11-R14 is coupled between a node of a reference voltage VREF generated by the band-gap reference circuit 360, and the ground, or VSS. In some embodiments, the resistors R11-R14 have the same resistance value. The first resistor ladder comprises a plurality of first intermediate nodes between adjacent resistors among the resistors R11-R14. Each of the first intermediate nodes is coupled to the first input of a corresponding compensator circuit among the comparator circuits OP1, OP2, OP3. As a result, different reference voltage values are provided by the first resistor ladder to the comparator circuits OP1, OP2, OP3.

The second resistor ladder comprising the resistors R21-R24 is coupled between a node of a positive power supply voltage, e.g., VDD, and the current mirror circuit 351 such that the current I_total flows through the second resistor ladder. In some embodiments, the resistors R11-R14 have the same resistance value. The second resistor ladder comprises a plurality of second intermediate nodes between adjacent resistors among the resistors R21-R24. Each of the second intermediate nodes is coupled to the second input of a corresponding compensator circuit among the comparator circuits OP1, OP2, OP3. As a result, different voltage values corresponding to the current I_total and the resistance value of the resistors R21-R24 are provided by the second resistor ladder to the comparator circuits OP1, OP2, OP3, to be compared with the corresponding different reference voltage values provided by the first resistor ladder.

In some embodiments, the output of a compensator circuit among the comparator circuits OP1, OP2, OP3 is at logic “1” when a voltage value provided by the second resistor ladder is greater than the corresponding reference voltage value provided by the first resistor ladder; otherwise, the output of the compensator circuit is at logic “0.” The outputs of the comparator circuits OP1, OP2, OP3 having logic “1” or logic “0” represent various bits of the digital signal 358. As a result, the current I_total corresponding to the total density of the memory macros 301, 302, 303 is converted to the digital signal 358 input to the encoder 357. In some embodiments, the encoder 357 is configured and/or operates in a manner similar to that described with respect to the encoder 257. In some embodiments, at least one of the analog control circuits 352, 352′ described with respect to FIGS. 3A, 3B is configured similarly to the analog control circuit 353. One or more advantages described herein are achievable by the memory device 300C, in accordance with some embodiments.

FIG. 3D is a schematic diagram of a memory device 300D, in accordance with some embodiments. In some embodiments, the memory device 300D corresponds to one or more of the memory devices 100, 200A, 200B, 300A, 300B, 300C. Components in FIG. 3D having corresponding components in FIGS. 2A, 2B, 3A, 3B, 3C are designated by the same reference numerals as in FIGS. 2A, 2B, 3A, 3B, 3C. For simplicity, memory macros beyond the memory macro 303 are not illustrated in FIG. 3D.

Compared to the memory device 300A, each of the indicator circuits in the memory macros 301, 302, 303, comprises a combination of a current source and a current mirror circuit. For example, the indicator circuit of the memory macro 301 comprises a current source I1 and a current mirror circuit 361 coupled between the current source I1 and the conductor 339, the indicator circuit of the memory macro 302 comprises a current source I2 and a current mirror circuit 362 coupled between the current source I2 and the conductor 339, the indicator circuit of the memory macro 303 comprises a current source I3 and a current mirror circuit 363 coupled between the current source I3 and the conductor 339, or the like.

The currents I1, I2, I3 correspond to the densities of the memory macros 301, 302, 303, and are mirrored by the corresponding current mirror circuits 361, 362, 363. The mirrored currents are supplied in the form of the current I_total on the conductor 339 to the current mirror circuit 351 of the global control circuit 355. At the global control circuit 355, the current I_total is converted to the digital signal 358 which is used to generate the control signals 354 for adjusting the analog bias generating circuit 240, as described herein. One or more advantages described herein are achievable by the memory device 300D, in accordance with some embodiments.

FIG. 4 is a schematic diagram of a memory device 400, in accordance with some embodiments. In at least one embodiment, the memory device 400 corresponds to one or more of the memory devices 100, 200A, 200B, 300A, 300B, 300C, 300D.

The memory device 400 comprises a memory macro 401 and a global analog circuit 430. In some embodiments, the memory macro 401 and global analog circuit 430 correspond to the memory macro 101 and global analog circuit 130. In at least one embodiment, the memory device 400 comprises one or more further memory macros (not shown) corresponding to one or more of the memory macros 102, . . . 10J.

The memory macro 401 comprises a memory array 410 corresponding to the memory array 110, an indicator circuit 411 corresponding to the indicator circuit 111, and a local control circuit corresponding to the local control circuit 120. In the example configuration in FIG. 4, the local control circuit of the memory macro 401 comprises a word line driver and power switch circuit 421 (referred to herein as “word line driver” for simplicity), a bit line driver and power switch circuit 422 (referred to herein as “bit line driver” for simplicity), an address decoder 423, a sense amplifier 424, and a control logic 425.

The address decoder 423 is configured to receive and decode a row address and a column address of a memory cell in the memory array 410 which is selected to be accessed in an access operation. The address decoder 423 is further configured to send the decoded row address and the decoded column address correspondingly to the word line driver 421 and the bit line driver 422.

The word line driver 421 is coupled to the memory array 410 via a plurality of word lines (not shown) as described with respect to FIG. 1. The word line driver 421 is configured to receive the decoded row address of the selected memory cell from the address decoder 423. In some embodiments, the word line driver 421 is configured to supply a voltage to a selected word line corresponding to the decoded row address, and a different voltage to the other, unselected word lines. In at least one embodiment, the word line driver 421 comprises one or more driving circuits or inverters. One or more of the voltages supplied by the word line driver 421 to the selected and unselected word lines are received from the global analog circuit 430, and correspond to one or more of the biases 142. In the example configuration in FIG. 4, the biases received by the word line driver 421 from the global analog circuit 430 comprise a read word line voltage for a read operation at a selected memory cell, and a write word line voltage for a write operation at a selected memory cell. In at least one embodiment, the word line driver 421 is configured to supply the read word line voltage to the selected memory cell through a read word line, and supply the write word line voltage to the selected memory cell through a different, write word line. Other biases are within the scopes of various embodiments.

The bit line driver 422 is coupled to the memory array 410 via a plurality of bit lines (not shown) as described with respect to FIG. 1. The bit line driver 422 is configured to receive the decoded column address of the selected memory cell from the address decoder 423. In some embodiments, the bit line driver 422 is configured to supply a voltage to a selected bit line corresponding to the decoded column address, and a different voltage to the other, unselected bit lines. In at least one embodiment, the bit line driver 422 comprises one or more driving circuits or inverters. One or more of the voltages supplied by the bit line driver 422 to the selected and unselected bit lines are received from the global analog circuit 430, and correspond to one or more of the biases 142. In the example configuration in FIG. 4, the biases received by the bit line driver 422 from the global analog circuit 430 comprise a read bit line voltage for a read operation at a selected memory cell, and a write bit line voltage for a write operation at a selected memory cell. Other biases are within the scopes of various embodiments.

In some embodiments, the local control circuit of the memory macro 401 further comprises a bit line selection circuit (not shown) configured to selectively couple one or more of the bit lines between the bit line driver 422 and the sense amplifier 424. In one or more embodiments, the bit line selection circuit comprises a switch, a transistor, a multiplexer, or the like.

The sense amplifier 424 is configured to perform a read operation, when coupled to a bit line by the bit line selection circuit. In some embodiments, the sense amplifier 424 is configured to determine a datum stored in a selected memory cell based on a read current on the bit line coupled to the selected memory cell and the sense amplifier 424. In at least one embodiment, the sense amplifier 424 further comprises a buffer for temporarily storing the read datum. The read data are output from the sense amplifier 424 as schematically shown in FIG. 4, e.g., through an input/output (I/O) pin, port or circuit.

The control logic 425 is an example of one or more sub-controllers configured to control other components and various operations in the memory macro 401. The control logic 425 is configured to receive control signals from a memory controller of the memory device 400. In the example configuration in FIG. 4, the control logic 425 is coupled to the word line driver 421, the bit line driver 422 and the sense amplifier 424, and is configured to control the word line driver 421, bit line driver 422 and sense amplifier 424 in various access operations. The control logic 425, or one or more further sub-controllers of the memory macro 401, is/are coupled to and configured to control one or more of the bit line selection circuit, buffers, I/O circuits, or the like, to coordinate operations of these circuits, drivers and/or buffers in access operations of the memory array 410. In one or more embodiments, the control logic 425 comprises circuitry of one or more of transistors, switches, logic gates, multiplexers, flip-flops, latches, or the like. The described memory macro configuration is an example, and other memory macro configurations are within the scopes of various embodiments.

The global analog circuit 430 comprises an analog bias generating circuit 440, a global control circuit 450, and a band-gap reference circuit 460. In some embodiments, the global analog circuit 430, the analog bias generating circuit 440, the global control circuit 450 and the band-gap reference circuit 460 correspond to one or more of the global analog circuits, the analog bias generating circuits, the global control circuit and the band-gap reference circuit described with respect to one or more of FIGS. 1, 2A-2B, 3A-3D.

In the example configuration in FIG. 4, the analog bias generating circuit 440 comprises LDO regulators VRBL LDO, VRWL LDO and charge pumps VWBL PUMP, VWWL PUMP configured to correspondingly supply the read bit line voltage, the read word line voltage, the write bit line voltage and the write word line voltage, as biases, to the memory macro 401. The analog bias generating circuit 440 further comprises an LDO regulator VPUMP LDO configured to provide regulated power 459 for the charge pumps VWBL PUMP, VWWL PUMP. In some embodiments, one or some or all of the LDO regulators VRBL LDO, VRWL LDO, VPUMP LDO and charge pumps VWBL PUMP, VWWL PUMP is/are adjustable in accordance with control signals 454 generated by the global control circuit 450.

The global control circuit 450 is configured to generate the control signals 454 based on density information included in an input signal 452 provided by the indicator circuit 411 and indicator circuits of other memory macros in the memory device 400. In some embodiments, the density information included in the input signal 452 corresponds to the total density of all memory macros in the memory device 400. In at least one embodiment, the indicator circuit 411 and any other indicator circuit in the memory device 400 are configured to provide the input signal 452 as a digital signal, and the global control circuit 450 comprises a digital control circuit, as described with respect to FIGS. 2A-2B. In at least one embodiment, the indicator circuit 411 and any other indicator circuit in the memory device 400 are configured to provide the input signal 452 as an analog signal, and the global control circuit 450 comprises an analog control circuit, as described with respect to FIGS. 3A-3D. In the example configuration in FIG. 4, the global control circuit 450 further provides a control signal to the band-gap reference circuit 460, and receives control signals from the memory controller of the memory device 400. In some embodiments, the control circuit 450 further comprises one or more of clock generators for providing clock signals for various components of the memory device, pre-decoder circuits, address latches, pulse generators, timing circuits, one or more input/output (I/O) circuits for data, address, clock and/or control exchange with external circuitry, one or more sub-controllers for controlling various operations in the memory device, or the like.

The band-gap reference circuit 460 is configured to provide a steady, reference voltage VREF to the LDO regulators VRBL LDO, VRWL LDO, VPUMP LDO and the global control circuit 450. In at least one embodiment, the reference voltage VREF is used in an analog-to-digital converter in the global control circuit 450, as described with respect to FIGS. 3C, 3D. The described global analog circuit configuration is an example, and other global analog circuit configurations are within the scopes of various embodiments. One or more advantages described herein are achievable by the memory device 400, in accordance with some embodiments.

FIG. 5A is a schematic circuit diagram of an LDO regulator 500A, in accordance with some embodiments. In some embodiments, the LDO regulator 500A corresponds to one or more LDO regulators described with respect to FIGS. 2A, 2B, 3A, 3B, 4.

The LDO regulator 500A comprises an input, an output, an operational amplifier OP, a P-type transistor M0, a resistor Rc, a capacitor Cc, and a voltage divider including resistors R51, R52. For simplicity, the input is designated by the corresponding input voltage VIN thereat, and the output is designated by the corresponding output voltage VOUT thereat.

The voltage divider comprises opposite ends correspondingly coupled to the output VOUT and a ground, and a middle node n1 between the resistors R51, R52. The transistor M0 comprises source/drains correspondingly coupled to the input VIN and the output VOUT, and a gate coupled in series with the resistor Rc and the capacitor Cc to the output VOUT. The operational amplifier OP comprises an inverting input coupled to a node of a reference voltage VREF (e.g., to an output of a band-gap reference circuit as described herein), a non-inverting input coupled to the node n1, and an output coupled to the gate of the transistor M0.

The operational amplifier OP comprises N-type transistors M1, M2, P-type transistors M3, M4, and a current source I0. The transistor M1 comprises source/drains correspondingly coupled to nodes n2, n3, and a gate corresponding to the inverting input of the operational amplifier OP and configured to receive the reference voltage VREF. The transistor M2 comprises a source/drain coupled to the node n2, another source/drain corresponding to the output of the operational amplifier OP and configured to be coupled to the gate of the transistor M0, and a gate corresponding to the non-inverting input of the operational amplifier OP and configured to be coupled to the node n1. The transistor M3 comprises a source/drain coupled to VDD, and another source/drain coupled to a gate of the transistor M3 and to the node n3. The transistor M4 comprises a source/drain coupled to VDD, another source/drain coupled to the output of the operational amplifier OP, and a gate coupled to the gate of the transistor M3 and to the node n3. The current source I0 is coupled between the ground and the node n2.

The current source I0 comprises a reference current source IREF and a current mirror circuit including N-type transistors M5, M6. The reference current source IREF is coupled between VDD and a node n4. The transistor M5 comprises a source/drain coupled to the node n2, another source/drain coupled to the ground, and a gate coupled to the node n4. The transistor M6 comprises a source/drain and a gate coupled to the node n4, and another source/drain coupled to the ground. The described configurations of the LDO regulator 500A, operational amplifier OP, and current source I0 are examples. Other LDO regulator, operational amplifier and/or current source configurations are within the scopes of various embodiments.

In at least one embodiment, the LDO regulator 500A is adjustable, and comprises at least one adjustable circuit element. In some embodiments, the at least one adjustable circuit element comprises at least one of an adjustable transistor, an adjustable capacitor, or an adjustable resistor. For example, at least one of the transistor M0, resistor Rc, capacitor Cc or transistor M5 is adjustable. In some embodiments, to adjust driving of the LDO regulator 500A, the transistor M0 is configured to be adjustable. In at least one embodiment, to adjust phase margin of the LDO regulator 500A, at least one of the transistor M0, resistor Rc, capacitor Cc, or current source I0 is configured to be adjustable. The current source I0 is adjustable by configuring the transistor M5 to be adjustable. An example configuration with the transistor M0 being adjustable is described with respect to FIG. 5B, an example configuration with the resistor Rc and capacitor Cc being adjustable is described with respect to FIG. 5C, and an example configuration with the transistor M5 being adjustable is described with respect to FIG. 5D. Combinations and/or modifications of the example configurations described with respect to FIGS. 5B-5D are within the scopes of various embodiments.

FIG. 5B is a schematic circuit diagram of an LDO regulator 500B, in accordance with some embodiments. In some embodiments, the LDO regulator 500B corresponds to one or more LDO regulators described with respect to FIGS. 2A, 2B, 3A, 3B, 4, 5A. Components in FIG. 5B having corresponding components in FIG. 5A are designated by the same reference numerals as in FIG. 5A.

In the LDO regulator 500B, the transistor M0 is an adjustable transistor and comprises a plurality of transistors M01-M04, and a plurality of switches TGm1-TGm3. Each of the transistors M01-M04 comprises a first source/drain, a second source/drain, and a gate. The first source/drains of the transistors M01-M04 are coupled together, and to the output VOUT. The second source/drains of the transistors M01-M04 are coupled together, and to the input VIN. Each of the switches is coupled between the gates of a pair of transistors among the transistors M01-M04. For example, the switch TGm1 is coupled between the gates of the transistors M01, M02, the switch TGm2 is coupled between the gates of the transistors M01, M03, and the switch TGm3 is coupled between the gates of the transistors M01, M04. In some embodiments, the transistors M01-M04 are identical, e.g., have the same size and/or driving strength.

In the example configuration in FIG. 5B, each of the switches TGm1-TGm3 is a transmission gate controlled to be turned ON or OFF by a control circuit, such as a global control circuit as described herein, through a pair of differential control signals. For example, the switch TGm1 is configured to be turned ON or OFF by a control signal S1 and an inverted version S1b thereof, the switch TGm2 is configured to be turned ON or OFF by a control signal S2 and an inverted version S2b thereof, and the switch TGm3 is configured to be turned ON or OFF by a control signal S3 and an inverted version S3b thereof. Each pair of control signals S1 and S1b, control signals S2 and S2b, and control signals S3 and S3b is a pair of differential control signals which are generated as control signals for adjusting an analog bias generating circuit, as described herein.

When all of the switches TGm1-TGm3 are turned OFF, the transistor M0 is configured by the transistor M01, and has a lowest driving strength. When one of the switches TGm1-TGm3 is turned ON, e.g., the switch TGm1 is turned ON, the transistor M0 is configured by two transistors M01, M02 coupled in parallel, and has about a double driving strength. When two of the switches TGm1-TGm3 are turned ON, e.g., the switches TGm1, TGm2 are turned ON, the transistor M0 is configured by three transistors M01, M02, M03 coupled in parallel, and has about a triple driving strength. When all three switches TGm1-TGm3 are turned ON, the transistor M0 is configured by four transistors M01-M04 coupled in parallel, and has about a quadruple driving strength. Thus, by turning ON or OFF one or more or all of the switches TGm1-TGm3, it is possible to adjust the driving strength of the transistor M0, thereby adjusting driving of the LDO regulator 500B.

In some embodiments, in response to an increased total density of memory macros in a memory device, a global control circuit of the memory device is configured to increase driving of one or more LDO regulators in an analog bias generating circuit of the memory device, by turning ON one or more switches in an adjustable transistor of the LDO regulator(s), such as the switches TGm1-TGm3. Conversely, in one or more embodiments, in response to a reduced total density of memory macros in a memory device, a global control circuit of the memory device is configured to reduce driving of one or more LDO regulators in an analog bias generating circuit of the memory device, by turning OFF one or more switches in an adjustable transistor of the LDO regulator(s). The described adjustable transistor configuration is an example. Other adjustable transistor configurations are within the scopes of various embodiments. For example, in one or more embodiments, each of the switches TGm1-TGm3 comprises a transistor and is controlled by a single control signal, instead of a pair of differential control signals. One or more advantages described herein are achievable by the LDO regulator 500B, an analog bias generating circuit or a memory device including the LDO regulator 500B, in accordance with some embodiments.

FIG. 5C is a schematic circuit diagram of an LDO regulator 500C, in accordance with some embodiments. In some embodiments, the LDO regulator 500C corresponds to one or more LDO regulators described with respect to FIGS. 2A, 2B, 3A, 3B, 4, 5A, 5B. Components in FIG. 5C having corresponding components in FIGS. 5A, 5B are designated by the same reference numerals as in FIGS. 5A, 5B.

In the LDO regulator 500C, the resistor Rc is an adjustable resistor and the capacitor Cc is an adjustable capacitor. In at least one embodiment, one of the resistor Rc and capacitor Cc is not an adjustable circuit element.

The resistor Rc being an adjustable resistor comprises a plurality of resistors Rc1-Rc4 coupled in series, and a plurality of switches TGr1-TGr3. Each of the switches TGr1-TGr3 is coupled in parallel with a corresponding resistor among the resistors Rc1-Rc4. For example, the switch TGr1 is coupled in parallel with the resistor Rc2, the switch TGr2 is coupled in parallel with the resistor Rc3, and the switch TGr3 is coupled in parallel with the resistor Rc4. In the example configuration in FIG. 5C, each of the switches TGr1-TGr3 is a transmission gate controlled to be turned ON or OFF by a control circuit, such as a global control circuit as described herein, through a pair of differential control signals (not shown). In some embodiments, the resistors Rc1-Rc4 are identical, e.g., have the same size and/or resistance value.

When all of the switches TGr1-TGr3 are turned ON, the resistor Rc is configured by the resistor Rc1, and has a lowest resistance value. When one of the switches TGr1-TGr3 is turned OFF, e.g., the switch TGr1 is turned OFF, the resistor Rc is configured by two resistors Rc1, Rc2 coupled in series, and has about a double resistance value. When two of the switches TGr1-TGr3 are turned OFF, e.g., the switches TGr1, TGr2 are turned OFF, the resistor Rc is configured by three resistors Rc1-Rc3 coupled in series, and has about a triple resistance value. When all three switches TGr1-TGr3 are turned OFF, the resistor Rc is configured by four resistors Rc1-Rc4 coupled in series, and has about a quadruple resistance value. Thus, by turning ON or OFF one or more or all of the switches TGr1-TGr3, it is possible to adjust the resistance value of the resistor Rc, thereby adjusting phase margin of the LDO regulator 500C.

The capacitor Cc being an adjustable capacitor comprises a plurality of capacitors Cc1-Cc3 coupled in parallel between a first node n5 and a second node n6, and a plurality of pairs of switches TGc1 and TGc2, TGc3 and TGc4. Each pair of switches correspondingly couples a first terminal and a second terminal of a corresponding capacitor to the first node n5 and the second node n6. For example, the pair of switches TGc1 and TGc2 correspondingly couples the terminals of the capacitor Cc2 to the nodes n5, n6, and the pair of switches TGc3 and TGc4 correspondingly couples the terminals of the capacitor Cc3 to the nodes n5, n6. In the example configuration in FIG. 5C, each of the switches TGc1-TGc4 is a transmission gate controlled to be turned ON or OFF by a control circuit, such as a global control circuit as described herein, through a pair of differential control signals (not shown). In some embodiments, the capacitors Cc1-Cc3 are identical, e.g., have the same size and/or capacitance value.

When all of the switches TGc1-TGc4 are turned OFF, the capacitor Cc is configured by the capacitor Cc1, and has a highest capacitance value. When one pair of switches is turned ON, e.g., the pair of switches TGc1, TGc2 is turned ON, the capacitor Cc is configured by two capacitors Cc1, Cc2 coupled in parallel, and has a capacitance value about half of the capacitance value of the capacitor Cc1. When both pairs of switches are turned ON, the capacitor Cc is configured by three capacitors Cc1, Cc2, Cc3 coupled in parallel, and has a capacitance value about one third of the capacitance value of the capacitor Cc1. Thus, by turning ON or OFF one or more of the pairs of switches TGc1-TGc4, it is possible to adjust the resistance value of the capacitor Cc, thereby adjusting phase margin of the LDO regulator 500C.

In some embodiments, adjusting a driving strength of the transistor M0 as described with respect to FIG. 5B and/or adjusting the current source I0 through adjusting a driving strength of the transistor M5 as described with respect to FIG. 5D also adjust(s) the phase margin of the LDO regulator. In at least one embodiment, adjustments of the phase margin of an LDO regulator in consideration of the total density of memory macros in a memory device comprising the LDO regulator is a non-linear relationship. In at least one embodiment, one or more simulations are performed to determine in advance how each of the transistor M0, resistor Rc, capacitor Cc, transistor M5 is to be adjusted by turning ON or OFF one or more corresponding switches in response to a specific value of the total density of memory macros in the memory device. The simulation results are then stored in a look-up table, such as the LUT 259. One or more advantages described herein are achievable by the LDO regulator 500C, an analog bias generating circuit or a memory device including the LDO regulator 500C, in accordance with some embodiments.

FIG. 5D is a schematic circuit diagram of a current source 500D, in accordance with some embodiments. Components in FIG. 5D having corresponding components in FIGS. 5A-5C are designated by the same reference numerals as in FIGS. 5A-5C. In some embodiments, the current source 500D is an adjustable circuit element and corresponds to a current source in an operational amplifier of one or more LDO regulators described with respect to FIGS. 2A, 2B, 3A, 3B, 4, 5A, 5B, 5C. For example, the current source 500D corresponds to the current source I0.

In the current source 500D, the transistor M5 is an adjustable transistor and comprises a plurality of transistors M51-M54 and a plurality of switches TGm5-TGm7 which are coupled in a manner similar to that described with respect to the adjustable transistor M0 in FIG. 5B. In some embodiments, by turning ON or OFF one or more or all of the switches TGm5-TGm7, it is possible to adjust the driving strength of the transistor M5, thereby adjusting the current source I0 in the operational amplifier OP, and also adjusting phase margin of the LDO regulator. As described with respect to FIG. 5C, one or more simulations are performed, in one or more embodiments, to determine in advance how the transistor M5 is to be adjusted by turning ON or OFF one or more corresponding switches in response to a specific value of the total density of memory macros in the memory device. The simulation results are then stored in a look-up table, such as the LUT 259. One or more advantages described herein are achievable by an operational amplifier, a LDO regulator, an analog bias generating circuit or a memory device including the current source 500D, in accordance with some embodiments.

FIG. 6 is a schematic circuit diagram of a charge pump 600, in accordance with some embodiments. In some embodiments, the charge pump 600 corresponds to one or more charge pumps described with respect to FIGS. 2A, 2B, 3A, 3B, 4.

The charge pump 600 comprises a first clock input configured to receive a first clock signal CLK, a second clock input configured to receive a second clock signal CLKB being an inverted signal of the first clock signal CKB, a plurality of diodes D1-D5, and a plurality of capacitors C1-C4 and CL. The diodes D1-D5 are coupled in series between a node of a power supply voltage, such as VDD, and an output indicated by a corresponding voltage Vo thereat. Each of the capacitors C1-C4 is coupled between the first clock input or the second clock input, and a node between a corresponding pair of diodes among the diodes D1-D5. For example, the capacitor C1 is coupled between the first clock input for the first clock signal CLK and a node between the diodes D1, D2, the capacitor C2 is coupled between the second clock input for the second clock signal CLKB and a node between the diodes D2, D3, the capacitor C3 is coupled between the first clock input for the first clock signal CLK and a node between the diodes D3, D4, and the capacitor C4 is coupled between the second clock input for the second clock signal CLKB and a node between the diodes D4, D5. The capacitor CL is coupled between the ground and the output Vo.

The charge pump 600 is configured to be adjustable by configuring one or more of the capacitors C1-C4 to be adjustable. For example, as shown in the example configuration in FIG. 6, the capacitor C4 is configured to be an adjustable capacitor, and comprises capacitors C41-C43 and switches TGc5-TGc8 coupled together in a manner similar to that described with respect to the capacitor Cc in FIG. 5C.

In some embodiments, by turning ON or OFF one or more of the pairs of switches TGc5-TGc6, and TGc7-TGc8, it is possible to adjust the capacitance value of the capacitor C4, thereby adjusting driving of the charge pump 600. In some embodiments, one or more of the capacitors C1-C3 are similarly configured to be adjustable. In at least one embodiment, how one or more of the capacitors C1-C4 is/are to be adjusted in response to a specific value of the total density of memory macros in the memory device is determined in advance by one or more simulations as described herein. The simulation results are then stored in a look-up table, such as the LUT 259.

In addition to or in lieu of adjusting one or more of the capacitors C1-C4, it is possible to adjust driving of the charge pump 600 in one or more embodiments by adjusting a frequency of the clock signals CLK and CLKB. For example, in one or more embodiments, in response to an increased total density of memory macros in a memory device, a global control circuit of the memory device is configured to increase driving of one or more charge pumps, such as the charge pump 600, by increasing the frequency of the clock signals supplied to the one or more charge pumps. Conversely, in one or more embodiments, in response to a reduced total density of memory macros in a memory device, a global control circuit of the memory device is configured to reduce driving of one or more charge pumps, such as the charge pump 600, by decreasing the frequency of the clock signals supplied to the one or more charge pumps. In some embodiments, the frequency of the clock signals CLK and CLKB is adjusted by the global control circuit at one or more components in a clock delivery network of the memory device. For example, the global control circuit changes a frequency ratio, by which a frequency divider circuit divides the frequency of an input clock signal provided by an oscillator, to obtain a different frequency for the clock signals CLK and CLKB. One or more advantages described herein are achievable by the charge pump 600, an analog bias generating circuit or a memory device including the charge pump 600, in accordance with some embodiments.

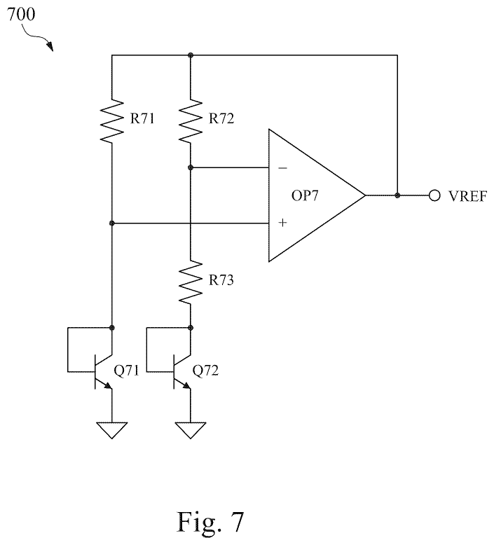

FIG. 7 is a schematic circuit diagram of a band-gap reference circuit 700, in accordance with some embodiments. In some embodiments, the band-gap reference circuit 700 corresponds to one or more band-gap reference circuits described with respect to FIGS. 3C, 3D, 4. In at least one embodiment, the band-gap reference circuit 700 is not configured to be adjustable.

The band-gap reference circuit 700 comprises an operational amplifier OP7, resistors R71-R73, and transistors Q71, Q72. The operational amplifier OP7 comprises an output configured to generate a reference voltage VREF as described herein, an inverting input coupled to first ends of the resistors R72, R73, a non-inverting input coupled to a first end of the resistor R71 and a first source/drain of the transistor Q71. A feedback connection couples the output of the operational amplifier OP7 to second ends of the resistors R71, R72. The transistor Q71 comprises a gate coupled to the first source/drain thereof, and a second source/drain coupled to the ground. The transistor Q72 comprises a gate coupled to a first source/drain thereof, and a second source/drain coupled to the ground. The first source/drain of the transistor Q72 is coupled to a second end of the resistor R73.

FIG. 8 includes a schematic circuit diagram and a truth table 810 of an encoder 800, in accordance with some embodiments. In some embodiments, the encoder 800 corresponds to one or more encoders described with respect to FIGS. 2B, 3C, 3D.

In the example configuration in FIG. 8, the encoder 800 is a 4-to-2 encoder, and comprises inverters INV1-INV4, AND gates AND0-AND3, and OR gates OR1, OR2. Four input bits Q1-Q4 of input data (e.g., a value of the total density of memory macros in a memory device) are provided to inputs of the inverters INV1-INV4. Outputs of the inverters INV1-INV4 are coupled to one or more inputs of the gates AND0-AND3. Outputs of the gates AND0-AND1 are coupled to inputs of the gate OR1, and outputs of the gates AND2-AND3 are coupled to inputs of the gate OR2. Outputs of the gates OR1, OR2 correspondingly provide two output bits A and B of an encoded value of the total density. The output bits A and B are obtained based on the input bits Q1-Q4, in accordance with the truth table 810 of the encoder 800. Other encoder configurations are within the scopes of various embodiments.

FIG. 9 is a schematic diagram of a look-up table (LUT) 900 for a control circuit, in accordance with some embodiments. In some embodiments, the LUT 900 corresponds to the LUT 259, and/or is determined in advance and used by a global control circuit for generating control signals to adjust an analog bias generating circuit in response to a total density of memory macros in a memory device, as described with respect to one or more of FIGS. 1, 2A-2B, 3A-3D, 4, 5A-5D, 6.

In the example configuration in FIG. 9, the LUT 900 includes a plurality of values or encoded values of the total density of memory macros in a memory device. The values or encoded values of the total density are designated as Code 1, Code 2, Code 3, . . . Code M (where M is a natural number) in LUT 900. Each of Code 1, Code 2, Code 3, . . . Code M, is stored in the LUT 900 in association with (e.g., in the same row) corresponding adjustments to be made by a global control circuit to an analog bias generating circuit.

For example, for an analog bias generating circuit comprising an adjustable LDO regulator having adjustable transistor M0, resistor Rc, capacitor Cc, as described with respect to FIGS. 5A-5C, in response to the total density of memory macros in the memory device corresponding to Code 2, the following adjustments are obtained from the LUT 900: the transistor M0 is to be adjusted by turning ON the switch TGm1, the capacitor Cc is to be adjusted by turning ON the pair of switches TGc1/TGc2, the resistor Rc is to be adjusted by turning ON the switch TGr1, or the like. Based on the adjustments read from the LUT 900 in response to Code 2, the global control circuit is configured to turn ON or OFF the corresponding switches, through one or more control signals as described herein, thereby optimizing the analog bias generating circuit. One or more advantages described herein are achievable by the LUT 900, a global control circuit or a memory device including the LUT 900, in accordance with some embodiments.

FIG. 10 is a schematic diagram of a memory cell 1000, in accordance with some embodiments. In the example configuration in FIG. 10, the memory cell 1000 is a SOT MRAM memory cell. Other memory configurations are within the scopes of various embodiments.

The memory cell 1000 comprises a magnetic tunnel junction (MTJ) structure comprising a free magnetic layer (sometimes referred to as “free layer”) 1019, a reference magnetic layer (sometimes referred to as “fixed layer” or “reference layer”) 1017, and a tunnel barrier layer 1018 between the free layer 1019 and the reference layer 1017. The memory device 100 further comprises a SOT layer 1020 in contact with the MTJ structure, a first selector S1 coupled in series with the SOT layer 1020 between a bit line BL and a write word line WWL, and a second selector S2 coupled between the MTJ structure and a read word line RWL.

The MTJ structure is configured to store a datum. The SOT layer 1020 is configured to enable the datum to be written, or stored, into the MTJ structure. Each of the selector S1 and selector S2 is a bi-directional circuit element configured to control a current to flow, or not to flow therethrough. In some embodiments, a selector is configured to be turned ON to pass current therethrough, in response to a bias (e.g., an analog voltage) applied across the selector being at or greater than a threshold voltage. A sign (positive or negative) of the bias corresponds to a direction of the current passing through the selector. In response to a bias applied across the selector being smaller than the threshold voltage, the selector is configured to be turned OFF. In at least one embodiment, at least one of the selectors S1, S2 is replaced with one or more transistors.

A datum stored in the MTJ structure corresponds to a magnetization of the free layer 1019 relative to a magnetization of the reference layer 1017. For example, when the magnetization of the free layer 1019 is anti-parallel to the magnetization of the reference layer 1017, the MTJ structure is in a high resistance state corresponding to a first logic state, e.g., one of logic “1” and logic “0”. When the magnetization of the free layer 1019 is parallel to the magnetization of the reference layer 1017, the MTJ structure is in a low resistance state corresponding to a second logic state, e.g., the other of logic “1” and logic “0”. The SOT layer 1020 is configured to set the MTJ structure into one of the first logic state and the second logic state. For example, when a current is caused to flow through the SOT layer 1020 in a first direction, the free layer 1019 is caused to have a magnetization anti-parallel to the magnetization of the reference layer 1017, corresponding to the first logic state being stored in the MTJ structure. When a current is caused to flow through the SOT layer 1020 in a second direction opposite to the first direction, the free layer 1019 is caused to have a magnetization parallel to the magnetization of the reference layer 1017, corresponding to the second logic state being stored in the MTJ structure. Examples of various access operations, e.g., under control of a memory controller such as the local control circuit 120, are described below.

In an example read operation of the memory cell 1000, an inhibition bias is applied across the selector S1 to turn OFF the selector S1 and/or to suppress sneak currents through other, unselected memory cells in the memory array. For example, the bit line BL is grounded (e.g., a bias of 0 V is supplied to the bit line BL) and an inhibition voltage is supplied to the write word line WWL. In some embodiments, a reference voltage other than 0 V is supplied to the bit line BL. A read voltage is supplied to the read word line RWL, turns ON the selector S2, and causes a read current Ir to flow along a read current path 1031 from the read word line RWL, through the MTJ structure and the SOT layer 1020 to the bit line BL. A current value of the read current Ir corresponds to the datum stored in the MTJ structure. For example, when the MTJ structure is in the high resistance state corresponding to, e.g., logic “0”, the read current Ir has a smaller current value. When the MTJ structure is in the low resistance state corresponding to, e.g., logic “1”, the read current Ir has a higher current value. A sense amplifier, e.g., as described with respect to FIG. 4, is electrically coupled to the bit line BL, and is configured to read the datum stored in the memory cell 1000 based on the sensed current value of the read current Ir. In at least one embodiment, the inhibition voltage in the read operation is half the read voltage.

In an example write “1” operation, i.e., a write operation for writing logic “1” into the memory cell 1000, an inhibition bias is applied across the selector S2 to turn OFF the selector S2 and/or to suppress sneak currents through other, unselected memory cells in the memory array. For example, the bit line BL is grounded (e.g., a bias of 0 V is supplied to the bit line BL) and an inhibition voltage is supplied to the read word line RWL. In some embodiments, a reference voltage other than 0 V is supplied to the bit line BL. A write voltage is supplied to the write word line WWL, turns ON the selector S1, and causes a write current Iw1 to flow along a write current path 1032 in a first direction from the write word line WWL, through the SOT layer 1020, to the bit line BL. The write current Iw1 flowing through the SOT layer 1020 in the first direction causes the free layer 1019 in the MTJ structure to have a magnetization parallel to the magnetization of the reference layer 1017, corresponding to logic “1” being written into the memory cell 1000. In at least one embodiment, the inhibition voltage in a write operation is half the write voltage, which is different from, or equal to, the read voltage.

In an example write “0 ” operation, i.e., a write operation for writing logic “0 ” into the memory cell 1000, an inhibition bias is applied across the selector S2 to turn OFF the selector S2 and/or to suppress sneak currents through other, unselected memory cells in the memory array. For example, the write word line WWL is grounded (e.g., a bias of 0 V is supplied to the write word line WWL) and an inhibition voltage is supplied to the read word line RWL. In some embodiments, a reference voltage other than 0 V is supplied to the write word line WWL. A write voltage is supplied to the bit line BL, turns ON the selector S1, and causes a write current Iw0 to flow along the write current path 1032 in a second direction opposite to the first direction from the bit line BL, through the SOT layer 1020, to the write word line WWL. The write current Iw0 flowing through the SOT layer 1020 in the second direction causes the free layer 1019 in the MTJ structure to have a magnetization anti-parallel to the magnetization of the reference layer 1017, corresponding to logic “0” being written into the memory cell 1000. In the described example configuration and/or operations, one or more of the described biases, inhibition voltage, reference voltage, read voltage, write voltage, or the like, correspond(s) to one or more analog biases described herein.

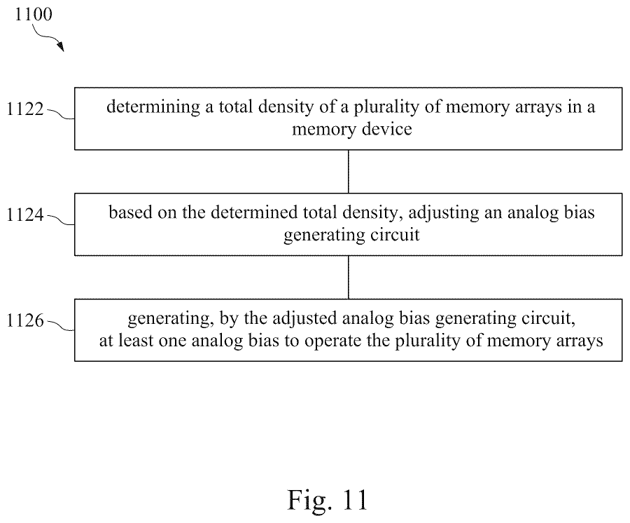

FIG. 11 is a flowchart of a method 1100, in accordance with some embodiments. In some embodiments, the method 1100 is performed by one or more memory devices, global analog circuits and/or circuitry thereof, as described with respect to one or more of FIGS. 1, 2A-2B, 3A-3D, 4, 5A-5D, 6-10. The method 1100 comprises operations 1122, 1124, 1126.

At operation 1122, a total density of a plurality of memory arrays in a memory device is determined. For example, as described with respect to FIGS. 2A-2B, densities of memory macros 201, 202, 203, . . . 20J are stored as one or more bits in corresponding storage circuits 231, 232, 233, . . . 23J, are input into corresponding adders AD1, AD2, AD3, . . . ADJ, and are summed up by the adders to obtain an input signal 252. The input signal 252 includes density information about the total density of the memory arrays in the memory device.

For another example, as described with respect to FIGS. 3A-3D, densities of memory macros 301, 302, 303, . . . 30J are represented by resistance values of corresponding resistors R1, R2, R3 or the like, and/or by current values of corresponding current sources I1, I2, I3, . . . IJ. Current corresponding to the densities of memory macros 301, 302, 303, . . . 30J are output to a conductor 339, resulting in a current I_total corresponding to the total density of the memory arrays in the memory device.

At operation 1124, based on the determined total density, an analog bias generating circuit is adjusted. For example, at least one adjustable circuit element of the analog bias generating circuit is adjusted, as described with respect to one or more of FIGS. 5A-5D, 6. In some embodiments, the adjustments to be made is obtained in response to a specific value of the total density of memory macros in the memory device, by referring to a predetermined LUT as described with respect to one or more of FIGS. 2B, 9. In at least one embodiment, based on the adjustments obtained from the LUT, a global control circuit is configured to turn ON or OFF one or more switches to adjust one or more adjustable circuit elements, as described with respect to FIGS. 5A-5D, 6.

As operation 1126, the adjusted analog bias generating circuit generates at least one analog bias to operate the plurality of memory arrays. For example, as described with respect to one or more of FIGS. 2A-2B, 3A-3D, 4, the adjusted analog bias generating circuit generates various biases, such as read/write voltages for one or more access operations in one or more of the memory arrays, in consideration of the determined total density of the memory macros in the memory device, such that the biases are sufficiently generated to ensure reliable and correct access operations, but without unnecessarily high power consumption. In some embodiments, voltage values of one or more biases are not affected by the described adjustments of the analog bias generating circuit; rather, a driving strength of the one or more biases is adjusted based on the total density of memory macros in the memory device. One or more advantages described herein are achievable by the method 1100, in accordance with some embodiments.

The described methods and algorithms include example operations, but they are not necessarily required to be performed in the order shown. Operations may be added, replaced, changed order, and/or eliminated as appropriate, in accordance with the spirit and scope of embodiments of the disclosure. Embodiments that combine different features and/or different embodiments are within the scope of the disclosure and will be apparent to those of ordinary skill in the art after reviewing this disclosure.

In some embodiments, a memory device comprises a memory array, an analog bias generating circuit configured to generate at least one analog bias and supply the at least one analog bias to the memory array, an indicator circuit configured to provide a parameter signal indicating a parameter of the memory array, and a control circuit configured to adjust the analog bias generating circuit in response to the parameter signal provided by the indicator circuit.

In some embodiments, a circuit comprises at least one of a low-dropout (LDO) regulator or a charge pump configured to generate at least one analog bias for at least one memory array. The at least one of the LDO regulator or the charge pump comprises at least one adjustable circuit element. The circuit further comprises a control circuit configured to, in response to an input signal, adjust the at least one adjustable circuit element of the at least one of the LDO regulator or the charge pump.

In some embodiments, a method comprises determining a total density of a plurality of memory arrays in a memory device, adjusting an analog bias generating circuit based on the determined total density, and generating, by the adjusted analog bias generating circuit, at least one analog bias to operate the plurality of memory arrays.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A memory device, comprising:
a memory array;
an analog bias generating circuit configured to generate at least one analog bias, and supply the at least one analog bias to the memory array;
an indicator circuit configured to provide a parameter signal indicating a parameter of the memory array; and
a control circuit configured to adjust the analog bias generating circuit in response to the parameter signal provided by the indicator circuit.

2. The memory device of claim 1, wherein
the parameter is a density of the memory array.

3. The memory device of claim 1, further comprising:
a plurality of memory arrays including the memory array; and
a plurality of indicator circuits including the indicator circuit,
wherein
the plurality of indicator circuits is configured to correspondingly provide a plurality of parameter signals including the parameter signal,
each of the plurality of parameter signals indicates the parameter of a corresponding memory array among the plurality of memory arrays, and
the control circuit is configured to adjust the analog bias generating circuit in response to the plurality of parameter signals.

4. The memory device of claim 3, further comprising:
a plurality of memory macros each comprising:
one of the plurality of memory arrays, and
a corresponding one of the plurality of indicator circuits.

5. The memory device of claim 3, wherein
each of the plurality of indicator circuits comprises:
a storage circuit configured to store a value of the parameter of a corresponding memory array among the plurality of memory arrays, and
an adder coupled to the storage circuit, and
the adders of the plurality of indicator circuits are serially coupled with each other into a string of adders, which is coupled to the control circuit.

6. The memory device of claim 5, wherein
the string of the adders is configured to provide, to the control circuit, a sum of the values of the parameter stored in the storage circuits of the plurality of indicator circuits, and
the control circuit comprises at least one of:
an encoder coupled to the string of the adders and configured to generate an encoded value of the sum,
a further storage circuit configured to store information corresponding to the sum, or
a look-up table configured to store different values of the sum or different encoded values of the sum in association with corresponding adjustments to be made by the control circuit to the analog bias generating circuit.

7. The memory device of claim 3, wherein
each of the plurality of indicator circuits is configured to generate a current corresponding to the parameter of a corresponding memory array among the plurality of memory arrays, and
the memory device further comprises a conductor coupling the plurality of indicator circuits to the control circuit to provide, to the control circuit, a total current being a sum of the currents generated by the plurality of indicator circuits.

8. The memory device of claim 7, wherein
each of the plurality of indicator circuits comprises one selected from the group consisting of:
a current source coupled to the conductor and configured to generate the current corresponding to the parameter of the corresponding memory array,
a resistor coupled between the conductor and a node of a power supply voltage, and having a resistance value corresponding to the parameter of the corresponding memory array, and
a combination of a current source configured to generate the current corresponding to the parameter of the corresponding memory array, and a current mirror circuit coupled between the current source and the conductor.

9. The memory device of claim 7, wherein
the control circuit comprises:
a current mirror circuit coupled to the conductor, and configured to generate a mirrored current of the total current on the conductor,
an analog-to-digital converter coupled to the current mirror circuit, and configured to generate a digital signal corresponding to the mirrored current, and
an encoder coupled to the analog-to-digital converter and configured to generate, from the digital signal, an encoded value corresponding to the total current.

10. The memory device of claim 9, wherein
the analog-to-digital converter comprises:
a plurality of comparator circuits, each having first and second inputs, and an output coupled to the encoder,
a first resistor ladder coupled to a node of a reference voltage, and having a plurality of first intermediate nodes correspondingly coupled to the first inputs of the plurality of comparator circuits, and
a second resistor ladder coupled to the current mirror circuit, and having a plurality of second intermediate nodes correspondingly coupled to the second inputs of the plurality of comparator circuits.

11. A circuit, comprising:
at least one of a low-dropout (LDO) regulator or a charge pump configured to generate at least one analog bias for at least one memory array, wherein
the at least one of the LDO regulator or the charge pump comprises at least one adjustable circuit element; and
a control circuit configured to, in response to an input signal, adjust the at least one adjustable circuit element of the at least one of the LDO regulator or the charge pump.

12. The circuit of claim 11, wherein
the at least one adjustable circuit element comprises at least one of:
an adjustable transistor,
an adjustable capacitor, or
an adjustable resistor.

13. The circuit of claim 11, wherein
the at least one adjustable circuit element comprises an adjustable transistor which comprises:
a plurality of transistors each having a first source/drain, a second source/drain, and a gate, and
a plurality of switches,
the first source/drains of the plurality of transistors are coupled together,
the second source/drains of the plurality of transistors are coupled together,
each of the plurality of switches is coupled between the gates of a pair of transistors among the plurality of transistors, and
the control circuit is configured to turn ON or OFF the plurality of switches to adjust the adjustable transistor.

14. The circuit of claim 11, wherein
the at least one adjustable circuit element comprises an adjustable capacitor which comprises:
a plurality of capacitors coupled in parallel between a first node and a second node, and
a plurality of pairs of switches,
each pair of the plurality of pairs of switches correspondingly couples a first terminal and a second terminal of a corresponding capacitor among the plurality of capacitors to the first node and the second node, and
the control circuit is configured to turn ON or OFF the plurality of pairs of switches to adjust the adjustable capacitor.

15. The circuit of claim 11, wherein
the at least one adjustable circuit element comprises an adjustable resistor which comprises:
a plurality of resistors coupled in series, and
a plurality of switches each coupled in parallel with a corresponding resistor among the plurality of resistors, and
the control circuit is configured to turn ON or OFF the plurality of switches to adjust the adjustable resistor.

16. The circuit of claim 11, wherein
the LDO regulator comprises an input, an output, an operational amplifier, a voltage divider, a transistor, a capacitor and a resistor,
the voltage divider comprises:
opposite ends correspondingly coupled to the output and a ground, and
a middle node between the opposite ends,
the transistor comprises:
source/drains correspondingly coupled to the input and the output, and
a gate coupled in series with the capacitor and the resistor to the output,
the operational amplifier comprises:
an inverting input coupled to a node of a reference voltage,
a non-inverting input coupled to the middle node of the voltage divider, and
an output coupled to the gate of the transistor, and.
the at least one adjustable circuit element comprises at least one of:
the transistor being an adjustable transistor,
the capacitor being an adjustable capacitor,
the resistor being an adjustable resistor, or
an adjustable transistor in a current source of the operational amplifier.

17. The circuit of claim 11, wherein
the charge pump comprises:
a first clock input configured to receive a first clock signal,
a second clock input configured to receive a second clock signal being an inverted signal of the first clock signal,
a plurality of diodes coupled in series between
a node of a power supply voltage, and
an output, and
a plurality of capacitors each coupled between
the first clock input or the second clock input, and
a node between a corresponding pair of diodes among the plurality of diodes, and
the at least one adjustable circuit element comprises at least one adjustable capacitor among the plurality of capacitors.

18. A method, comprising:
determining a total density of a plurality of memory arrays in a memory device;
based on the determined total density, adjusting an analog bias generating circuit; and
generating, by the adjusted analog bias generating circuit, at least one analog bias to operate the plurality of memory arrays.

19. The method of claim 18, further comprising:
receiving an input signal upon powering up the memory device; and
thereafter, stopping receipt of or ignoring the input signal,
wherein said determining comprises determining the total density of the plurality of memory arrays based on the input signal.

20. The method of claim 18, wherein
said adjusting comprises adjusting at least one of:
at least one of driving or phase margin of a low-dropout (LDO) regulator of the analog bias generating circuit, or
driving of a charge pump of the analog bias generating circuit.
